(19) United States
(12) Patent Application Publication
(10) Pub. No.: US 2017/0205150 A1
(43) Pub. Date: Jul. 20, 2017

(54) Chillflex Microcooling System

(71) Applicant: ChillFlux, Inc., Berkeley, CA (US)

(72) Inventors: Lilla M. Safford Smith, Berkeley, CA (US); Jim Chih-Min Cheng, Berkeley, CA (US)

(21) Appl. No.: 15/300,093

(22) PCT Filed: Apr. 3, 2015
(86) PCT No.: PCT/US2015/024367

§ 371 Date: Sep. 28, 2016

Related U.S. Application Data
(60) Provisional application No. 61/975,200, filed on Apr. 4, 2014.

(51) Int. Cl. F28D 15/04; H01L 23/427; H05K 7/20

(52) U.S. Cl. CPC F28D 15/043; H05K 7/20; H01L 23/427; F28D 15/0233

(57) ABSTRACT

Aspects of the invention include microcooling system that provides a simple, unitary, two dimensional construct with capacity to remove heat effectively from the internal structures of microelectronic devices.

### CROSS-REFERENCE TO RELATED APPLICATION

Pursuant to 35 U.S.C. §119(e), this application claims priority to United States Provisional Application Ser. No. 61/975,200 filed on Apr. 4, 2014, the disclosure of which is herein incorporated by reference.

### INTRODUCTION

Cooling systems have been critical to key advancements in mechanical device development. Cooling elements are necessary components for most machinery. These critical cooling elements reduce the heat of working parts to a level where the device can function optimally without confounding problems of heat degradation. Heat challenges in machinery can include accelerated material fatigue, undue expansion of parts, change of state or viscosity in liquid elements, increased friction on surfaces, among others. Large cooling systems typically rely on pumps for circulation of the cooling fluid through pipes which direct the flow with specific pipe configurations of specifically designed diameters and shapes. These active pumps requiring electrical power or external motion force to the device itself in order to provide movement to the cooling liquid. The fluid flows in large systems are also gravitationally susceptible. Thus, depending on the orientation of the system to the axis of the earth, the cooling system will perform differently.

With the advent of microelectronic devices, cooling systems have again taken a key role in the advancement of new technologies. Cooling systems make possible overall device design innovations and increased functionality, and represent key constraining factors to design opportunities. Unfortunately, much of the centuries long experience in large cooling systems does not translate to the much smaller form factors of microelectronic devices.

Cooling fluids in microelectronic devices have very different fluid dynamics characteristics than in traditional systems, and often have regular and unpredictable changing orientations to gravity. The benefit of microcooling systems is that capillary force can become a major factor in the fluid dynamic forces if the channels are below about 100 μm. Currently, even the micro scale portion of currently available microcooling devices is constructed of separate parts assembled together to make a complete system. Multiple components are assembled via welds, interconnects, etc., in order to construct the devices.

Asphia et al. teaches a physical pipe system moving fluid in vapor pipes with an improved evaporator using a two layer wicking structure. This more complex structure increases the pressure, pumping the loop further and avoiding the need for an external power system. (U.S. Pat. No. 8,720,530, issued May 13, 2014)

Nelson et al. teaches a multi-material joined system, enabling a fixed curve in the device. An external power system is provided. (U.S. Pat. No. 6,529,377, issued Mar. 4, 2003)

Increasingly, limitations in heat removal are constraining the otherwise exponential increase in the accelerating capacity of microelectronic devices to deliver increased functionality at the smaller and smaller form factors that have characterized this industry.

### SUMMARY

The innovative ChillFlex microcooling system provides, for the first time, an elegantly simple, unitary, two dimensional construct with unprecedented capacity to remove heat effectively from the internal structures of microelectronic devices. The ChillFlex capability for previously unavailable multiple sharp bend radius without degradation of functionality permits direct contact with heat generating structures, and thus optimal heat dissipation.

The unique capabilities of ChillFlex will enable a new surge forward in microelectronic devices with previously unattainable small form factors, a cornucopia of new capabilities, and an increased quality and performance of current features. ChillFlex enjoys ribbon-like structural flexibility, dynamic functional flexibility in real-time response to changing heat dissipation challenges, and flexibility in design choices to meet a wide range of currently unmet microelectronic form factor and functional needs.

Unlike currently available microcooling systems which suffer loss of functionality when made smaller, unexpectedly, the elegantly simple ChillFlex pump-free and pipe-free design enjoys improved functionality with decreasing dimensions. ChillFlex design innovations also permit the system to have multiple components designed in a comprehensive, integrated device.

The ChillFlex device can physically conform to a variety of constrained, challenging internal microelectronic device structures. Remarkably, ChillFlex enjoys a radius of curvature from 0.5-3.0 mm, specifically from about 1-2.5 mm, and more specifically about 1.50 mm, with little or no compromise of the devices heat transfer capabilities.

This ChillFlex curvature can occur spontaneously as in the ribbon-like embodiments of ChillFlex. In that case, the ChillFlex device is insinuated around internal microelectronic device components. However, when ChillFlex is engineered to serve an additional function as a structural component of the microelectronic device, and thus is more ridged in form, the radius of curvature can be designed into the ChillFlex device and pre-bent in fabrication.

Counterintuitively, ChillFlex provides multiple fluid loops with minimal internal structure. Remarkably, these flow loops automatically respond to changing heat removal demands by reconfiguring to provide a flow pattern of optimal performance.

Without the need for physical pipes, ChillFlex generates fluid loops analogous to those provided in a traditional loop heat pipe, but without the need for piping. Traditional loop heat pipes have actual piping systems. ChillFlex delivers a pipe-less, planar device with the functionality analogous to that of traditional loop heat pipes. The innovative ChillFlex design allows ChillFlex's uniquely thin profile, which is critical to practical applications in microelectronic devices.

ChillFlex is constructed in the plane of a piece of material. Within that plane, to optimize for the thin structure, multiple fluid loops are provided without the need for piping through its integrated design. The device instead uses a combination of wicks and micro-channels. These fluid loops allow the device to function in a much wider range of power inputs. By example, ChillFlex functions from about 0.5 W-15 W, specifically from about 4 W-8 W and more specifically at about 6 W.

A major innovation of the ChillFlex device is its planar structure which incorporates carefully designed fluid mechanics to instigate and support multiple fluid loops when functioning. Previous microcooling device designs have a three dimensional structure, in contrast to ChillFlex's planar design. The physically constructed loop heat pipes of the prior art are large and complex, limiting the ability to reduce the size of these devices.

By contrast, ChillFlex's much simplified design employs bare bones components. These components are integrated into a surface structure to keep the system simple as possible. As a result, the current complexity required in microcooling systems is stripped away, so that the base function of what is required is retained. To achieve this unique simplicity of design while maintaining and increasing functionality, the ChillFlex structural features create prescribed multiple fluid loops that form spontaneously when presented with heat needing dissipation.

ChillFlex's unitary design has many advantages. Physical compliancy and flexibility is achieved without resorting to multiple distinct segments along the length of the device. Thus, flexing the ChillFlex device need not leave a permanent bend. ChillFlex is not required to be aligned along a plane or board. ChillFlex has a physical total thickness well below that of known phase change devices (ex. 500μm). ChillFlex is structured to minimize any distortion of channel geometries which would otherwise cause significant drops to operational efficiency when turning corners or moving out of plane.

The ChillFlex structure is unique in its ability to be constructed with a very thin profile. ChillFlex has a thinness profile from about 10μm-650μm, specifically from about 50μm-500μm, more specifically from about 100μm-300 μm and most specifically about 200μm. In some embodiments, ChillFlex has a thinness profile of from about 50μm-650μm, specifically from about 100μm-550μm, more specifically from about 200μm-450μm, and most specifically about 300μm.

ChillFlex can have multiple heat inputs and sinks without discrete interconnects or other separate parts, while still maintaining flow of heat in a prescribed direction. In this way, the device prevents reverse flow of heat due to application of heat at a sink location. ChillFlex requires no pumps (e.g. magnetohydrodynamic, electrokinetic). ChillFlex has no inlets or outlets. The ChillFlex apparatus also achieves enhanced performance beyond heat pipes and vapor chambers through leveraging physical phenomena such as increasing interlineevaporation during operation.

ChillFlex has other unique capabilities. ChillFlex can move heat out-of-plane. ChillFlex can conform to any surface where the hotspots can form whether they be planar or not. ChillFlex can be flexible while remaining thin enough to bypass other components on the surface of boards such as jumper wires and interconnects. ChillFlex incorporates the higher efficiency of loop heat pipe systems in a scaled, compact platform. ChillFlex does not require expensive and often exotic materials such as diamond or GaN to achieve efficient spreading of heat.

Finally, ChillFlex allows for routing of the heat from multiple heat sources to multiple, distant heat sinks, while preventing heat flow in the opposite direction several inches to feet away in a single piece apparatus for minimal losses during heat transport and maximum robustness.

### Discovery

The ChillFlex pipeless fluid loop innovation was discovered unexpectedly when some of the present inventors encountered a fabrication error during prototyping. As rectangular devices, during fabrication microcooling devices are welded all the way to the edge of the channels. While engaging in a prototyping effort, some of the present inventors inadvertently welded the device further out. This construction error created a channel that was on the edge of the device, producing a moat-like structure.

When tested, this welding error produced an additional circulation loop. This unexpected discovery was not originally planned in the device design, but is key to the unique functionality of the ChillFlex system. The multiple, responsive fluid loops this discovery enabled are further described in the detailed description of the invention section, below.

### Design Optimization

Insights from prior theoretical work of Nelson et al. (International Journal of Heat and Mass Transfer 49, 2006, 1603-1618) and Honda et al. (Experimental Thermal and Fluid Science 28, 2004, 159-169) are useful in designing optimal ChillFlex systems for a range of applications. These two major microcooling device theories are divergent and unbuildable in practice. However, with new insights achieved by the innovative ChillFlex system, these theories can now help inform design choices to optimize the final ChillFlex system for specific uses and structural environments.

Nelson and Honda's theories were aimed at increasing the overall efficiency of microcooling devices by increasing the efficiency of their evaporator. Nelson published ideas on altering the ratio of width to height in surface structures in order to create a thin film to increase the heat transfer coefficient. Honda proposed increasing the efficiency of the evaporator by creating rough surfaces. Thus Nelson and Honda offered two radically different methods to accomplish essentially the same goal. Honda proposed making the evaporator surface as rough as possible to make thin films. Nelson proposed making very specific ratios of defined structures. Thus, Honda and Nelson's evaporator optimization proposals come from radically different directions.

In practice, microcooling devices based on either theory were impractical to produce. Nelson's structures required a very specific ratio of height to width that was either too small to be made at the micro scale or required a large evaporator that was impractical. To build a functioning Nelson device, that ratio would have to be manufactured as a much larger device, since the whole evaporator system would be much larger. Ultimately, the Nelson device was very impractical to make as a thin and small device.

Honda's requirement for surface roughness demands a surface which results in an unacceptable increase to the actual resistance to the cooling fluid circulating in the device. As a result, while increased boiling of the cooling fluid at the evaporator is achieved, it is at the cost of less and less circulation. As a result, any benefit from the Honda modification would be lost in the actual device creation. Implementation of this work would need to balance increased boiling with increased circulation, but there were no specifics on how to accomplish this in a system.

Unexpectedly, the innovations of the ChillFlex system permits, for the first time, the integration of the otherwise disparate Nelson and Honda structures and their practical applications to a functioning cooling system. ChillFlex system benefits from each of these disparate theories, and using a very different approach gleans the advantage of both. The work of both Nelson and Honda were focused on creating a surface that can evaporate fluid very efficiently, without appreciating the effect on the overall system. By example, with Honda's work, while evaporation is very high, within a device, this approach is very impractical because of all the losses that occur with it. ChillFlex system provides a foundation where one component of that higher level can be incorporated into a system that circulates and functions.

### Unitary Design

ChillFlex is planar device which incorporates all components in a one piece based build, avoiding the necessity of complex physical components. This design is a radical departure from the present modular microcooling systems where necessary loop heat pipes and other features required connecting disparate components by making junctions during device fabrication.

Because of this opportunity for a full unitary design, ChillFlex components work together as a highly symbiotic system. As an example, Asphia et al (ibid) has taught an excellent evaporator, which is then connected to a condenser and other components with pipe. The design is modular, with each individual component joined together to produce the final assembly. By contrast, ChillFlex has all the necessary components integrated into one device. A key teaching of ChillFlex is a design which provides a whole system working together without separating any of the necessary working components.

The ChillFlex unitary design avoids the risk of leakage points, which are intrinsic in currently available heat removal system. Robustness and reliability is extremely important in micromechanical systems. However, with greater miniaturization, the ability to hold tolerances to assure proper connectivity becomes increasingly challenging. The ChillFlex unitary design is fabricated as one build with no moving parts, minimizing or eliminating failure points.

### Cooling Fluid

A wide range of fluids can be selected from designing a ChillFlex system to a particular need. The specific experimental examples provided below employ methanol as the ChillFlex device 1 cooling fluid 24. However, a variety of fluids may be employed, such as water, acetone, alcohols, chlorofluorocarbons, and halogenated fluorocarbons.

Each fluid or fluid combination has their advantages and disadvantages for a particular embodiment of the ChillFlex system. By example, methanol enjoys the advantage of a high latent heat. Thus, methanol absorbs a lot of heat going from liquid to vapor. Methanol has very good wetting properties. With methanol's low contact angle, methanol has considerable capillary pressure when it goes through a wicking structure.

Water has a very high latent heat, almost twice that of methanol. Thus, water is also a good option for the ChillFlex cooling fluid. Water also has the advantage of being non-toxic, such as in medical applications. However, the surface wetting properties of water are not as good as methanol's. This difference can be important in certain applications.

Additionally, the temperature of the early device is currently provided so that, in the case of personal microelectronic devices, the user can actually hold the external device. This is distinct from such devices as the Apple Lap Top computers which specifically state that the devices cannot be used on a user's lap. If water is used as the cooling fluid for the ChillFlex device, there are means to reduce the temperature of the overall boiling point. However, the complexity of the system design is also increased.

Methanol's boiling point is far lower than water's boiling point. Thus, as an intrinsic fluid to be used within the device methanol is less complex in that one fluid can be used with minimal complexity to the device filling. By contrast, water requires a design with far more fluid filling and sealing capabilities. As such, water requires a design with far more complexity in the component as well as its flow characteristics in the cavity in order for the ChillFlex system to work correctly.

As a base example, a cooling system for components in a power module will need to handle higher temperatures while absorbing more heat. In that case, a cooling fluid like water could be appropriate, as water will boil at a higher temperature but will also absorb almost twice as much heat as other fluids. Therefore, the 6 W capability will depend on the selected fluid and can be adjusted as needed.

### XY Orientation

The ChillFlex design utilization of multiple axes (the XY orientation) for heat transport is a new approach in microelectronic cooling. Previously, microcooling theory has focused on a single axis for heat transport in considering heat pipes (X or Y), loop heat pipes (X or Y) and vapor chambers (Z), and in scaling the thickness or overall height of the device down (Z). This can be a Z direction focus to thin the device or using the device to move heat primarily in the Z direction. As a result, as the currently available designs push height down, the actual performance of the device decreases quadratically, or even exponentially. This current design paradigm largely decreases how much heat as a whole the device can transport, as well as its thermal conductivity and all other thermal metrics.

The ChillFlex design represents a breakthrough in this long standing design limitation. Unexpectedly, as the ChillFlex design went thinner in the Z height, rather than losing performance or holding performance at the same level, there is an increase in performance, as demonstrated in tests performed by some of the present inventors. This reverse effect is highly unexpected for such a device, and differentiates ChillFlex from currently available devices. To achieve this leap forward, the ChillFlex design does not just consider one component of the system, but takes into consideration the system features as a whole when determining the design. As described above, unexpectedly, a mistake made by some of the present inventors in formulating an early system and then fabricating it, lead to insight that vastly improved the system.

Currently available microelectronic cooling systems are focused on heat transfer in the Z direction. By example, several current devices have a vapor chamber based system with the main objective of transferring in the Z direction, from one face of the device to the other. As a result, the point where the heat is applied will have the most heat dissipation, while other portions of the system may well not be working. Since some heat will move laterally, those fluid loops are technically set up, and individually non-defined, for that one point. Wherever the heat comes in, the loop is expressed from that spot. There are no specific structures internally that would try to direct the heat to be deposited at another specific spot.

Regarding the uniquely available radius of curvature available with the ChillFlex design, pinching of the device on bending can, in some cases, produce sonic flow. Thus, there is the potential for degrading the function of the ChillFlex device. As such, when considering design opportunities, materials should be selected that bend to the necessary degree without pinching. The thickness of the material, brittleness, the structure, etc., can all be taken into account. Once of the advantages of the channels in the fluid return area will be helpful in retaining the open channel structure when the device is bent.

When the cooling fluid flows around a corner, there will be an increase in pressure loss, analogous to pipe losses. Because of the wick structure having sufficient pressure to cause circulation in the ChillFlex device, the additional pressure loss will not hinder the functionality of the system. Any potential losses can be accommodated with section of a wick structure with increased capillary pressure.

Fully integrated system

The ChillFlex device is disruptive to the industry. The ChillFlex unprecedented advantages are unexpected. The ChillFlex design includes specific components created to control the flow within a full system. Designing the system as a whole enables a system with much improved functionality. But each component does not need to be individually defined. By example, the wick could be generalized. Thus, it is not because of one specific structure that the system gains its unique advantages.

In designing the ChillFlex system, the system must be considered as a whole. Otherwise the resulting fabricated device will not function, or will function sub-optimally. By example, in current devices, a vapor chamber, loop-heat pipe, or a heat pipe, require engineering specifically at one single component in order attempt to drive the entire performance.

Simply scaling down larger cooling systems has serious limits. As the system is scaled down, the amount of heat which can be moved is in the range of about 1-3 W. As a result, microelectronic device manufacturers typically employ a solid for cooling, such as a graphite sheet, as there is not much gain to installing a more complex heat removal system.

By contrast, ChillFlex system can move 1-6 watts in its integrated system without the need for external structures or external connections. This larger heat transfer has numerous benefits to the device to be cooled. ChillFlex is thus enabling of an entire system on the exterior of that device.

### Manufacturing Techniques

The fabrication of the ChillFlex wicks by laser micro-manufacturing has special advantages. The high aspect ratios which are key in the wick structure is easily accomplished with lasers. By contrast, wet-etch techniques or micro-masking method utilizing lithography would be more time consuming, and selectivity between the materials would be more limited.

The ChillFlex device is one of the first micro-manufactured, fluid systems for thermal applications that is manufactured by laser. Laser fabrication is a standard technique already used in the semiconductor industry. The application of these established techniques to this function will be understood by the ordinary skilled artisan.

Standard stamping techniques can be used for fabrication of the larger features of the ChillFlex design. In these areas, the aspect ratios or very close tolerance control over the uniformity of those features is not of the same criticality of the finer features.

The ChillFlex coolant channels can be formed by a variety of techniques such as photolithographic methods including metal chemical etching, hot stamping and laser etching. Sealing the system can be performed through variations of fusion bonding, ultrasonic welding and laser welding.

ChillFlex is filled with degassed coolant. The filling ports can be sealed through a variety of methods including welding the ports closed, soldering and crimping the fill tubes shut. Many standard techniques used in metal and plastic systems for hermetically sealing and patterning microfluidic systems are all possible methods for manufacture of the ChillFlex system.

### Implementation in Microelectronic Devices

The physical and functional flexibility of the ChillFlex system provides, for the first time, a means of moving the heat from not just one component onwards, as with currently available systems, but actually from multiple components. The ChillFlex system provides the opportunity for multiple inputs of hit into the system, and multiple outputs to the heat to areas preferable for heat transmission out of the device.

The uniquely effective ChillFlex system provides cooling of the application processor. However, device battery recharge time and overall life also benefits from ChillFlex. The flexibility of mounting position and efficiency of heat removal allows more uniform across such a large surface.

The ChillFlex system can extend the life of a device by about 10%-200%, specifically from about 50%-100% and more specifically about 75%. Similarly, use of the ChillFlex system can extend the working life of the device's battery by 10%-200%, specifically from about 50%-100% and more specifically about 75%.

Currently available heat pipes in cellphones have one or two heat pipes along the edge of the device in an effort to pull out the heat from one disparate part using a very thin sheet. There are serious limitations to these systems. Movement of that heat is very poor in the heat pipe. This limitation compounds the difficulties in having something so far downstream trying to move that heat out of the device.

By contrast, ChillFlex can be in direct contact with the actual heated components. This unique characteristic provided by the flexible ChillFlex form factor allows its positioning virtually anywhere in a cell phone device. In other embodiments, ChillFlex can be a structural unit, and is designed and built for that capacity.

Most currently available cooling device are not easily incorporated into commercial personal electronic devices. Current devices don't take into consideration electromagnetic interference (EMI) or a mechanical build that would allow other components to be mounted onto it. These limitations are reflected in the failure of industry to adopted currently available cooling devices into their products.

The radically redesigned ChillFlex device overcomes many of these current limitations. The unique manufacturability ChillFlex device is critical for manufactures needing to integrate this component into their products. ChillFlex device design eliminates the need for power input, which is a key factor for effective integration into products.

Currently, personal electronic device manufactures rely on graphite sheets for heat dissipation, in part because a rectangular structure fits with their devices form factor requirements. By contrast, standard heat pipe devices are radically different structures. The ChillFlex system has a breakthrough rectangular structure with heat pipe capabilities. This allows manufactures to replace like with like form factors. Thus, ChillFlex represents a huge commercial change, with dimensions and form factor already being used, but providing the many advantages of phase-change device.

Currently available devices do not have the capacity to scale down without radially diminishing their capacity. Manufactures are requiring 200 μm thinness. However, currently available devices at 700-800 μm already have limited their ability to hold power down to around 2 watts. When the form factor is push even further, current cooling devices do not have any advantage over currently used systems. Additionally, at these extremely small form factors, the devices engineering robustness is substantially degraded. By example, in such a thin scheme, just having a finger touch the device would crush it flat.

By contrast, ChillFlex can retain thickness to maintain structural rigidity when required. However, ChillFlex can be mounted in other places on the phone in a much thinner form factor too, while still retaining functionality. ChillFlex retains flexibility of mounting, but also flexibility of usage.

### Robust Structure in Mobile Devices

As a result of a mistake in an experimental system, it was discovered by some of the present inventors that it was possible to have an effective cooling structure without the middle cavity in that device which is characteristic of currently available cooling system. This ChillFlex structural breakthrough adds that extra structural rigidity because it is a planar sheet and a key weld line is eliminated.

As a result of the ChillFlex system breakthrough design, the failure points in the ChillFlex system very few. This robust quality of ChillFlex will be reflected in standard tests to which a mobile device company, computer manufacturer, and other electronic device manufacturers, will subject candidate cooling systems. By example, multiple drop tests, multiple of bend tests etc., are normally conducted. The failures points typically expected from a cooling device are very few for the ChillFlex system. Some of the present inventors have achieved a 1 cm bend radius in the system.

By contrast, a currently available heat pipe system is typically 600μm thick. When subjected to even a slight bend, the internal wick structure is severely compromised, resulting in a 30% yield even in the controlled conditions of a manufacturing line. This physical vulnerability to bends means the devices do not approach the capacity required by the mobile industry needs. Even a slight crimp in currently available heat pipe systems destroys the functionality of the wick. In turn, the useful functionality of the device ceases

When the ChillFlex device is bent, there is no component that will fracture. A benefit of this quality is the opportunity for a small bend radius, allowing unprecedented physical conformability to any component in a system needing cooling. In contrast, the Nelson et. Al. (ibid) device has a bend radius of no smaller than 10 cm. However, even in that case, in actual practice, to make this a hermetic structure to avoid fluid loss, bending the device even 10 cm would stop practical functionality. With the same challenge, the ChillFlex device retains functionality.

### Fluid Dynamics and Pipe-Free Design

The ChillFlex device pipe-free design renders special advantages over currently available microelectronic cooling devices. This ChillFlex design feature is important in eliminating the need for a pump otherwise required to facilitate movement of fluid.

The demands on a pump are increased by pipes directing fluid flow. There are substantial pressure losses along these pipes. Thus, a pump must be more powerful and larger the farther the fluid travels. This is due to the dynamics of the system, and the frictional force produced in the pipes as the fluid flows against the pipe walls.

The cooling fluid movement in the ChillFlex device are all low Reynold's number fluid flow. With a low Reynold's number fluid flow, there is very little gravitational effect. Additional, the way in which the fluid moves produces very minimal eddy currents. Any eddy currents that may be created are very consistent. Thus, the eddy currents ChillFlex device will not be random or constantly changing. Any eddy current would behave exactly the same way all the time.

The flow in the ChillFlex device is naturally laminar, as the fluid used is a Newtonian fluid, Because the design and components in the ChillFlex device very thin and small, low Reynold's numbers are produced, and the fluid flow is laminar. The capillary forces within the ChillFlex device are advantageous to its function. The fluid loops described in the Detailed Description section that follows are an actual flow of physical fluid, rather than thermal flow. For this purposed of this application, fluid includes liquid, vapor, droplets and other phases of the fluid.

### BRIEF DESCRIPTION OF THE DRAWINGS

FIG. 1 is a generalized cross-sectional view of the ChillFlex system showing 3 fluid loops.

FIG. 2 illustrates an embodiment of the ChillFlex system at relatively low temperatures where the primary fluid loop is dominant in the system,

FIG. 3 illustrates an embodiment of the ChillFlex system at relatively medium temperatures where the second fluid loop dominates,

FIG. 4 illustrates the ChillFlex system flow dynamics relatively much higher temperatures when the third fluid loop forms,

FIG. 5 illustrates of boundaries of ChillFlex design functionality for correct wick selection,

FIG. 6 illustrates of boundaries of ChillFlex design functionality when secondary wick is absent,

FIG. 7 illustrates alternate wick structures available for ChillFlex,

FIG. 8 illustrates an alternate evaporator,

FIG. 9 is an alternate embodiment providing a basic deigned for the fluid design channel,

FIG. 10 illustrates ChillFlex incorporated with several bends in a cellphone design.

### DETAILED DESCRIPTION

The ChillFlex system is an innovated, virtual loop heat pipe for cell phones and other electronics requiring heat transport and cooling in ultra-compact form factors (includes servers in data centers). A heat pipe behaves as if it is a super heat conduction material, because it uses phase change to maximize heat transfer. This behavior makes it an ideal tool for future personal electronic devices, as more heat is produced in a concentrated area than even the most thermally conductive materials can effectively spread.

The ChillFlex system functions with the same basic principles as other heat pipes. ChillFlex has a condenser area and an evaporator area with liquid and vapor circulation between the two. The liquid transport is capillary driven and follows the general principles of the Laplace-Young equation and Darcy's law.

The ChillFlex evaporator uses thin film boiling. This feature is in distinction to currently available heat pipes which use nucleate or bubble boiling. This new evaporation technique is one of the key technological advances of the ChillFlex device. Other advances include a new internal architecture that promotes fast heat removal via multipath unconstrained loops, which functions at room temperature, and a flexible method to integrate the final structure.

The ChillFlex device is a disruptive innovation utilizing new knowledge on thin film hydrodynamics. Phase change devices have been a frequent choice in recent years as a solution to overheating in high heat flux situations because of the high thermal transport that happens when evaporation occurs, due to latent heat effects. The ChillFlex used this advantageous method by designing from the ground up with appreciation of microscale behavior. The ChillFlex device was designed from the bottom up with capillary forces planned for pumping and evaporation utilizing thin film evaporation behavior. This bottom up approach led to a novel, very efficient technology.

The ChillFlex design draws on prior heat pipe technologies, and uses some of these basic concepts. Usually a heat pipe is circular with a wicking material covering the inside surface and a hollow center. During operation, heat is added to the evaporator side of the heat pipe and removed via condensation on the other side. Once the fluid condenses it is drawn back to the hot side by the wicking structure creating a loop.

A key challenge in classic heat pipe technologies is the surface resistance created by having fluid move one way slowly and vapor move the other quickly. The mass flow rates of these two medias must balance creating a large velocity differential. These two opposing motions and interactions can create problems including condensation before the end of the pipe, evaporation in undesirable places that chokes off new flow (commonly known as vapor lock), increased shear forces and unstable driving pressure.

The ChillFlex system uses new techniques to avoid these limitations. Evaporation is the fundamental advantage of phase change devices, and the ChillFlex design maximizes this behavior. Maximization of a thin film can lead to very efficient phase change in small areas. Research done by some of the present inventors achieved heat transfer coefficients of 50,000 W/m2 K, when using a simplified version of the ChillFlex evaporator.

ChillFlex can achieve an effective convective heat transfer coefficient (h-W/m̂ 2K) of from about 2,000-100,000, specifically from about 5,000-50,000, and more specifically about 20,000.

### Efficiency

The efficiency of the ChillFlex system is a measure of its ability to dissipate the required heat from a heat source. This removal has two parts: one is transport from the immediate vicinity of the hot chip and the second is dissipation into air or whatever media the device is surrounded by. Current cell phone chips usually produce 1.5 to 3 W of heat at the source, with new technology moving towards 5 W. These power requirements will only increase with further adoption of 4G communication technologies and moving into the next generation of radios.

### Room Temperature Function

The ability of ChillFlex to function at room temperature increases its usefulness, while meeting consumer expectations. ChillFlex can utilize fluids and fluid mixtures which will have little impact if released due to catastrophic failure. Water, methanol and FC-72 can be used in ChillFlex. The ChillFlex devices have different internal pressures to shift the boiling behavior into the required range. Methanol already evaporates at low temperatures and only needs pressures down to 0.5 atmospheres to boil around 45° C., which requires minimal vacuum. FC-72 also boils at low temperatures and requires 0.25 atmospheres of pressure to boil around 45° C. This method also allows the pressure to be dropped even lower if a certain level of superheat is required to get efficient behavior. Another advantage of these fluid choices is that hermeticity requirements are lower than water-based heat pipes.

### Thinning

Smartphone manufacturers need heat pipes under 0.5 mm to practically incorporate them into their devices. Consumer demand for thin smartphones requires them to be low mass, easy to handle and possible to store easily in pockets.

The ChillFlex system is uniquely positioned to address this challenge in that it does not require a sintered or twisted wick structure in the middle of the vapor chamber adds thickness to a heat pipe. The ChillFlex fluid channels are separate from the vapor channels, allowing both to have adequate space without adding thickness. Additionally, aluminum can be used for the ChillFlex structure. This material is easily obtained in sheets of 0.25 mm and less.

ChillFlex manufacturing techniques used to manipulate material into the needed channel geometries does not depend on material thickness. These techniques work on thick and thin materials alike. Thus, increasingly thinner materials can be used.

### Flexibility

Flexibility is a key feature of ChillFlex devices that makes them convenient and simple to add to a cellular device. A drawback to currently available heat pipe structures is difficulties in integration. Adding a heat pipe currently requires a large redesign to the remainder of the phone. The added cost, poor yield and limited performance boost from ultra-thin heat pipes are also impediments to commercial adoption.

ChillFlex devices change this paradigm. The thin aluminum and other metal ChillFlex devices have intrinsic bendable characteristic due to properties of the raw materials. The flexibility of the device can be engineered by careful selection of alloys and processes used in the manufacture the base material. This aids in making the devices bendable with very small radii of curvature. A challenge of the bendable ChillFlex device is that deformation during bending that can potentially narrow flow channels. This is mitigated by smart channel geometry that includes structural reinforcement designed into the devices.

### Basic ChillFlex System

In its simplest form, the ChillFlex system has an evaporator mounted to a heat source such as a microprocessor. The ChillFlex condenser can be attached to or integrated directly into a heat sink, such as a cooling block or a large surface like the back cover of a cell phone, at the other end of a circuit board. The ChillFlex device, which is hermetically sealed with no non-condensable gases, is filled partially or wholly with vapor and liquid of the coolant.

When temperature of the heat source reaches or exceeds the critical temperature for evaporation of the coolant, the coolant in the evaporator will evaporate. The vapor region carries the vapor to the condenser where the vapor is cooled and condenses into liquid. The liquid return channels then carry the coolant back to the compensation chamber and then it enters the wick in the evaporator where it evaporates and the loop begins again.

The ChillFlex system is passive as it scavenges the thermal energy from the heat source to drive the closed-loop. With input heat flux primarily at the evaporator and heat flux out primarily at the condenser, a thermal gradient is established resulting in a pressure differential which drives the vapor from the evaporator to the condenser.

Ideal gas law applies in this system since the volume is held constant and the system is hermetic. As a result, pressure and temperature are directly proportional. As long as the vapor region is larger than the liquid capillaries and coolant vapor is ejected at high speeds from the evaporator area, a long distance throw of the heat of >1 ft is achieved. This is similar to the principal of operation of closed loop macroscale loop heat pipes used to cool power generation facilities.

The large difference in size between the two requires the need for monotonically decreasing channel geometry to drive the fluid to the evaporator during the start-up transient of ChillFlex. This aids the system in overcoming high acceleration environments and periods where there is a possibility of dryout. The capillary pressure established in the coolant channels leading to the evaporator overall keeps the system independent of gravity and acceleration forces up to and depending on the size of the evaporator channels, 25 g.

### Wick

In some embodiments, the ChillFlex evaporator is assembled and sealed using a floor and ceiling foil. The wick channels and evaporator surface are patterned typically into the floor foil. A vapor region can be etched into the ceiling and floor foil to increase the space available to the vapor reducing pressure losses.

The small wick channels are typically microscale in their dimensions. These will be ideally between 4-50 μm in width if methanol is used as a coolant. This design feature helps ensure sufficient capillary draw of fluid into the evaporator similar to transpiration in nature.

The small wick channels prior to the vapor region serve a second purpose of forming a hydraulic lock between the evaporator and coolant channels from the condenser to maintain sufficient fluidic resistance and preferential pressure release such that vapor evaporated from the evaporator travels quickly to the condenser. The hydraulic lock also forms a thermal barrier being largely coolant liquid which has low thermal conductivity. This hydraulic lock area can be straight from the wick to the compensation chamber.

Alternatively, the hydraulic lock area can be serpentine without or with dielectric thermal barriers between the serpentine structures such as air cavities. This increases the thermal resistance, and thus maximizes the pressure differential and driving force for the ChillFlex system. In this embodiment, a fluid reservoir is positioned between the wick, which created the hydraulic lock and the fluid return channels to offer additional thermal resistance and additional fluid during the start-up transient of ChillFlex. In another embodiment, the fluid reservoir can be positioned off the side of the main channels; designed to be a compensation chamber. In an additional embodiment, the fluid reservoir can be removed entirely allowing for the wick to connect directly to the fluid return channels. In this case a fractal transport network (with capillaries increasing in number towards the wick) could be utilized to mitigate the effects of fluidic resistance as the channels become smaller.

All these constructs aid toward maximizing thermal resistance between the wick and coolant channels. This also limits the chances of dryout. The vapor space increases the surface area from which evaporation can occur. The wick dimensions can be reduced further into the nanoscale regime to provide further capillary draw and to allow the unit to be minimally influenced by the effects of acceleration. Additionally, the structures are created to maximize heat throw, primarily through the use of prescribed channels to drive fluid around the loop in one direction and isolate the vapor from the liquid with a physical barrier.

### Evaporator

The ChillFlex evaporator is designed to maximize the interline layer to increase direct vaporization of the fluid. Fluid in the interline layer is several hundred nanometers to tens of microns thick. This thickness is dependent on the coolant used. The thickness allows thermal conduction to occur ideally through the fluid removing the need for superheat for evaporation.

Too thin fluid thicknesses encounter adhesion forces such as Van der Waals forces which bind the fluid molecules on the surface. This requires superheat to be applied for evaporation to occur. Too thick fluid layers have inadequate conduction of heat to the surface and thus requires superheat, above the normal boiling temperature, to be applied for evaporation to occur. Bubbles generated in evaporators in most 2 phase cooling systems only have a small amount of their surface in the interline region. Therefore evaporation becomes quite inefficient.

By establishing a thin interline meniscus over a larger area of the wick, evaporation can occur in the ChillFlex system with minimal bubble generation required and little to no superheat. The result is highly efficient heat transfer from the heat source into ChillFlex.

The floor can be channels to carry the fluid into the wick such as shown in the vapor chamber diagram. In some embodiments, these floor channels can contain surface texturing such as post arrays (micro and nano) and surface roughening to increase the surface area and help to spread out the fluid meniscus.

The vapor chamber ceiling also contains texturing. This texturing can be a variety of structures from parallel channels and oblique channels to posts and pyramidal columns. The floor channels bring in the fluid and spread it out on the floor of the wick and feeding coolant to the ceiling structures. The ceiling structures then spread out the fluid meniscus more to dial in the meniscus to the interline region.

This two layer approach allows efficient formation and spreading of the interline region over a large portion of the evaporator. In typical operation, 25% or more of the surface is ideally interline. This results in thermal conductivity increases of an order or more compared to copper (400 W/m·K).

### Fluid Flow

Vapor generated in the ChillFlex evaporator is preferentially directed toward the condenser through the large vapor space due to the pressure differential between the evaporator and condenser. The condenser can have a post-like or a cooling fin type structure to increase surface area for cooling of the vapor to liquid. The increased surface area also helps to draw more fluid to the condenser.

In an alternative embodiment, surface texturing by roughening the surface and channels can also be added to the ChillFlex condenser for the same purpose. There are multiple methods including growing nanopillars to increase surface area or roughening the surface with laser pulses. All these methods are applicable for ChillFlex optimized for the intended application.

While there can be one capillary, multiple channels can be utilized to balance out the overall loop. This maintains sufficient pressure differential through capillary forces to allow the circulation of the coolant around the loop. For thermal isolation between the vapor channels and liquid capillaries, an open isolation channel can be patterned through both floor and ceiling foils.

### Multiple Plane Mounting

One of the chief advantages of the ChillFlex system is its flexibility to be mounted between points at different elevations and in different planes for three dimensional movement of the heat. This allows mounting and movement of heat from one point to another similar to wire interconnects in electronics.

The ChillFlex system can be mounted in a standard planar geometry. ChillFlex's unique thin cross-section minimizes overall mass and volume needed for the thermal ground plane. In such a planar geometry, ChillFlex can be laminated onto and between PCBs to carry heat from heat sources on the boards to the edge where the heat can be rejected.

Its compact, thin structure also allows ChillFlex to be mounted in spaces too small for current cooling systems with high thermal conductivity such as macro-scale loop heat pipes. A major distinguishing feature of ChillFlex from other cooling systems is that scaling its size, especially cross-sectional thickness. This results in improving performance such as in thermal conductivity and acceleration resistance. This is quite unlike vapor chamber systems where increasing thickness is necessary to allow sufficient vapor space, especially so the vapor can diffuse and “throw” the heat sufficient distance away from the heat source.

ChillFlex can achieve a long distance heat throw of from about 2-12 inches, specifically from about 3-6 inches, and more specifically about 4 inches. ChillFlex can also achieve and acceleration resistance of from about 7 g-20 g, specifically from about 8 g-12 g, and more specifically about 10 g.

ChillFlex is still bound by fluidic resistance limitations, though since these are not reached until the channels drop to −100 nm in diameter, the overall system can be reduced over about an order in thickness and volume compared to currently available cooling systems.

### Power Free

The ChillFlex system is passive in nature, and does not require electrical power such as a thermoelectric unit. The heat source(s) itself provides necessary energy for function. ChillFlex's flexibility allows routing of heat to much more convenient spots for heat sinks. By example, tablet computers flip-chip configurations for processors are ideal to maximize computing power. Ideally the heat would be routed to the backside of the tablet device where there is significant area for heat dissipation and no active sense circuitry such as touchpads.

Because ChillFlex can be mounted to the flipped chip and routed such that the condenser side is mounted to the backside of the tablet, such systems can perform optimally as thermal issues are being managed. While ChillFlex can work for a single heat source and a single heat sink, multiple evaporator points can be provided to feed to the same vapor channels which can feed to the same or multiple condenser points.

The ChillFlex heat routing is remarkably flexible. As long as the standard design rules for ChillFlex are adhered to, multiple evaporators and condensers can be built into one ChillFlex system. This can be done in a single large ChillFlex sheet orientation with the channel wiring patterned within. Alternatively, the system can be in a fan orientation where the condensers have channels which fan out to the individual heat sources through attached ChillFlex strips. Another routing scenario is for rack systems where boards are mounted extremely close to each other.

The ChillFlex system can be mounted to hotspots on the boards and threaded between the boards to a heat sink out from between the boards. Due to the full fluid loop which separates the vapor and liquid to separate channels and minimizes thermal crosstalk, the ChillFlex system becomes more robust against conditions such as dry-out.

Due to the flexibility of materials which can be used to construct the system from metals to plastics, a variety of coolants can be used with high effectiveness. Coatings can also be added to the channels to modify the surface energy of the surfaces to tailor the capillary pressures. Additives can be added to the coolant to further enhance or modify operating temperatures of the ChillFlex system.

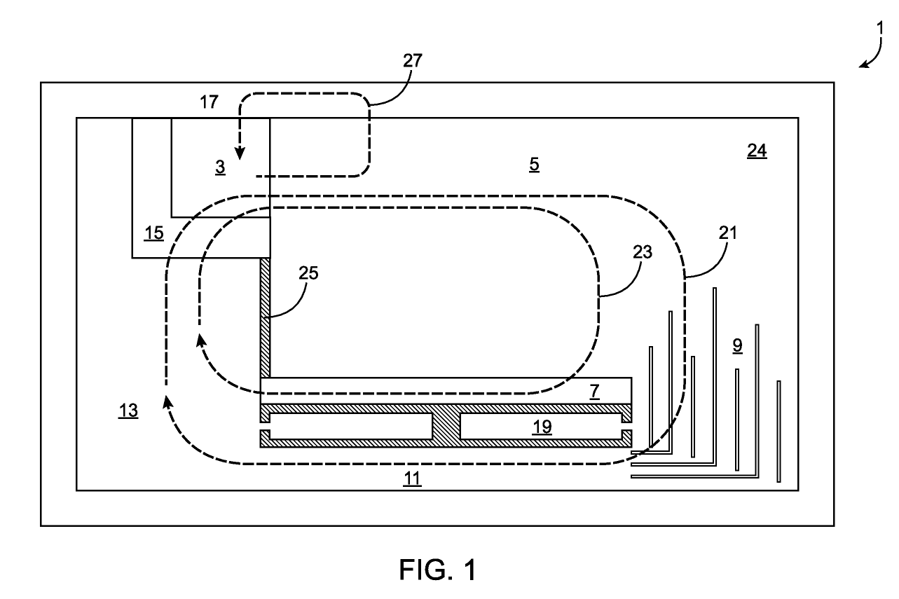

FIG. 1 provides a generalized front view of the internal structures of ChillFlex system. ChillFlex device 1 is typically rectangular in shape, and includes a number of structural design features. The features shown here are for demonstration only, and can be adapted to meet many different commercial product requirements, as is obvious to one of ordinary skill in the art in view of the teaching provided in this patent disclosure.

The ChillFlex device 1 structural design features are designed, engineered, and coordinated in form and relative position to accomplish the unprecedented needs responsive fluid dynamics flow patterns of the ChillFlex system. The innovative ChillFlex device 1 design endows the ChillFlex system with the unique ability to reconfigure its function responsively to changing heat removal requirements. Each feature defines an area in which the coolant fluid can travel and change its state of matter as needed to accomplish the unique cooling capacity of the ChillFlex system.

As shown in FIG. 1, evaporator structure 3 within the ChillFlex device 1 provides an evaporator surface and area which promotes and facilitates the evaporation of the cooling fluid 24. Vapor region 5 within ChillFlex device 1 and adjacent to evaporator structure 3 is positioned downstream from the evaporator structure 3 in the fluid dynamics flow. Vapor region 5 is the largest open area within ChillFlex device 1, providing a relatively high volume chamber to aid in its function. Evaporator structure 3 accomplishes a change in state in the cooling fluid 24 to a generally vapor state, although as described below, the state of matter can be a complex mix of states, and with a heat challenge level responsive, dynamic flow pattern.

Downstream in the fluid dynamics flow from vapor region 5 is secondary wick 7. Secondary wick 7 is a design feature of the ChillFlex device 1 that facilitates and maintains the various fluid loops described below.

Downstream in the fluid dynamics from vapor region 5 is condenser region 9. Condenser region 9 provides the change in state of the cooling fluid 24 arriving from vapor region 5 in a vapor form into droplets, liquid and mix states where appropriate, often in response to changing heat dissipation requirements.

Return flow area 11 is positioned downstream in the fluid dynamics flow from condenser region 9. Return flow area 11 serves as a conduit of cooling fluid 24 to compensation chamber 13. Compensation chamber 13 is typically the second largest open area in ChillFlex device 1. Primary wick 15 is positioned downstream in the fluid dynamics flow from compensation chamber 13. Primary wick 15 feeds cooling fluid 24 into evaporator structure 3, completing the ChillFlex device 1 general fluid dynamics flow circuit.

Wall region 19 is situated between vapor region 5 bordered by secondary wick 7, and return flow area 11. Wall region 19 abuts compensation chamber 13 condenser region 9 on either end. Wall region 19 serves to divide some of the flow areas, described below.

Holding additional cooling fluid 24 flow patterns is a moat-like structure surrounding the aforementioned structures, the furthest external thin channel 17. External thin channel 17 can have internal structures, not specifically illustrated in FIG. 1. External thin channel 17 supports several flow dynamics in the other areas of ChillFlex device 1, as described below.

The size of vapor region 5, return flow area 11, condenser region 9, and compensation chamber 13, can all be modified to optimize the device for an intended use. By example, the ChillFlex design can be rendered thinner, such into the 100μm range, by designing vapor region 5, return flow area 11, condenser region 9, and compensation chamber 13 to accommodate that change. In that range, all the ChillFlex components function in these modified dimensions in the physical XY dimensions of those regions. The size, proportions, and other factors of the ChillFlex design components can also be modified to accommodate different fluids for use in cooling fluid 24. By example, a cooling fluid 24 with a very low viscosity could be optimized for by the ChillFlex design. Changes to the wick 3 can accommodate low viscosity fluids such as a fluorocarbon fluid. In this embodiment, return flow area 11, condenser region 9, and compensation chamber 13 would be designed to larger dimensions to accommodate the choice of cooling fluid 24. Those would be the regions that would be dimensionally modified. Dimensional changes could also be made for cooling fluid 24 in the case of a high viscosity liquid. Key to the unique dynamic adaptation capabilities of ChillFlex system are the dynamic flow patterns supported and facilitated by the various engineered structural features of the ChillFlex device 1. Three major fluid loops can be instigated and sustained by the engineered structural features of the ChillFlex device 1. These fluid loops are flowing vapor and, liquid.

As illustrated in FIG. 1, the various, more dominant circulation patterns of fluid flow in the ChillFlex system are shown in three major fluid loops. Each of these loops automatically and responsively becomes more dominant relative to the other major flow patterns as appropriate to the particular level of heat removal challenge. The shift in the relative strength of these major fluid flow patterns optimizes the effectiveness of the ChillFlex system at various levels of heat removal requirements.

The three main fluid loops of the ChillFlex system described below are purposely engineered, actual structural fluid loops, not inadvertent randomly occurring loops. These ChillFlex system loops are predefined by the ChillFlex structure to function in a predictable, predesigned manner.

For the purposes of this application, in the following description as well as elsewhere in the application, the terms “up” and “down” in the context of this application refer to relative positions in the two dimensions structure, rather than orientation to ground level.

Primary fluid loop 21 is the largest fluid loop, in size, in the ChillFlex system. In function, the cooling fluid 24 in primary fluid loop 21 flows from evaporator structure 3 through vapor region 5. From this point, the cooling fluid 24 in primary fluid loop 21 flows down through condenser region 9, through return flow area 11, and up through compensation chamber 13. From compensation chamber 13, the cooling fluid 24 in primary fluid loop 21 flows through primary wick 15 and back through evaporator structure 3, completing the full flow loop.

Wall region 19 is the structure specifically designed to promote the instigation and sustenance of the movement of cooling fluid 24 in primary fluid loop 21 in the ChillFlex system. Aspects of the specificity of the primary fluid loop 21 are formed by wall region 19, a barrier engineered to create fluid loop 21.

An alternative embodiment of wall region 19 in order to create a separation between second wick 7 and return flow area 11, wall region 19 can be a through hole (not illustrated here). Wall region 19 would be an air pocket or void used as an insulator. This alternate embodiment facilitates fluid loop 21 by limiting the parasitic heat flow through second wick 7 into return flow area 11 through its heat insulating capacity.

The cooling fluid 24 in second fluid loop 23 flows from evaporator structure 3 to vapor region 5 down into secondary wick 7. The cooling fluid 24 in second fluid loop 23 then flows through secondary wick 7 back into compensation chamber 13. Finally, the cooling fluid 24 in second fluid loop 23 travels again through primary wick 15. Barrier region 25 is a barrier structure designed to partially define second fluid loop 23. This is an additional barrier to keep a barrier between vapor region 5 and compensation chamber 13.

The cooling fluid 24 in third fluid loop 27 flows from evaporator structure 3 into vapor region 5. From vapor region 5, the cooling fluid 24 in third fluid loop 27 flows up through external thin channel 17 and back into evaporator structure 3. Third fluid loop 27 is specifically designed in external thin channel 17. A major function of external thin channel 17 is to create third fluid loop 27.

A key factor in ChillFlex design is that cooling fluid 24 in primary fluid loop 21 is the lower power loop of the three fluid loops. Cooling fluid 24 in primary fluid loop 21 works in the lowest power ranges. The cooling fluid 24 in primary fluid loop 21 functions at about 0-5 W, where fluid circulation begins to start. The fluid circulation will go up to about 3-3.5 W depending on the fluid selected. Primary fluid loop 21 functions typically in this lower range. Secondary wick 7 and primary wick 15 are specifically designed to have any cooling fluid 24 that enters these areas leave them rapidly because of capillary forces. Thus, there is no static cooling fluid 24 in these components. By contrast, a similar region in compensation chamber 13 is meant to have cooling fluid 24 remain, and fill primary wick 15. As a result, there are low capillary forces for cooling fluid 24 in in compensation chamber 13. The cooling fluid 24 from secondary wick 7 then drains into compensation chamber 13 to keep compensation chamber 13 full, as does cooling fluid 24 from return flow area 11.

Phase change in cooling fluid 24 within primary fluid loop 21, second fluid loop 23 and third fluid loop 27 as well as other subsidiary fluid loops is critical to the function of the ChillFlex device. By example, in primary fluid loop 21, phase change occurs as the liquid cooling fluid 24 is going into the vapor phase in evaporator structure 3. The vapor of cooling fluid 24 then goes along the path of primary fluid loop 21 into vapor region 5. By the time cooling fluid 24 reaches condenser region 9, it has cooled, and then goes back into the liquid phase.

Thus, the cooling fluid 24 goes from the vapor phase to the liquid phase in condenser region 9. Once cooling fluid 24 is in the liquid phase, the capillary forces in return flow area 11 circulates cooling fluid 24 back around to where it is deposited into compensation chamber 13. When there is enough heat to drive cooling fluid 24 again, cooling fluid 24 will get pulled into primary wick 15 by capillary forces and follow that loop again.

When the ChillFlex device is operating at higher power ranges, the vapor phase of cooling fluid 24 is moving at faster velocities. In that case, the cooling fluid 24 movement in primary fluid loop 21 all the way from evaporator structure 3 to condenser region 9 becomes very difficult. This dynamic occurs some portion of the time. Then second fluid loop 23 begins to form. The faster moving vapor phase where there are droplets of liquid forming in vapor region 5 is then pulled into secondary wick 7. These droplet forms of cooling fluid 24 are wicked into secondary wick 7 by capillary forces. These droplet forms of cooling fluid 24 return to compensation chamber 13, where they get wicked into primary wick 15, and subsequently go through a phase change.

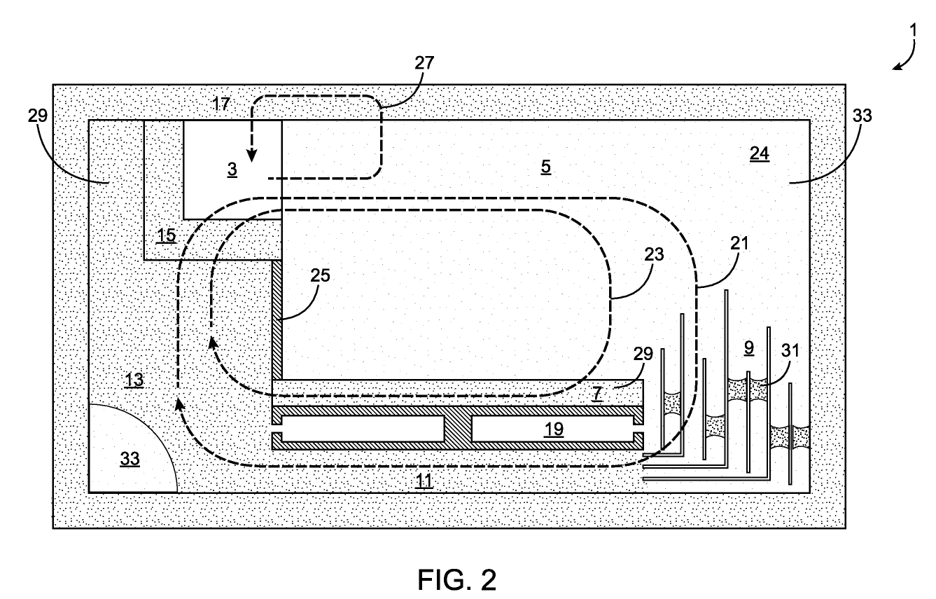

FIG. 2 illustrates an embodiment of the ChillFlex system where primary fluid loop 21 is dominant in the system. As illustrated in FIG. 2, in primary fluid loop 21, hash marks indicate liquid and vapor phases of cooling fluid 24 as it flows through the ChillFlex system. Cooling fluid 24 in vapor region 5 is primarily in the form of vapor 33. In condenser region 9 during primary fluid loop 21, the formation of droplets 31 in cooling fluid 24 occurs. Cooling fluid 24 in return flow area 11 is primarily liquid. Some portion of cooling fluid 24 in compensation chamber 13 can be in vapor form.

In vapor region 5, cooling fluid 29 is primarily vapor 33. As cooling fluid 29 enters condenser region 9, formation of droplets 31 in cooling fluid 24 occurs. When cooling fluid 24 in condenser region 9 enters return flow area 11 it goes into first liquid phase 29. First liquid phase 29, vapor phase 33, and second liquid phase 31, are collectively cooling fluid 24.

During the flow of cooling fluid 24 in primary fluid loop 21, cooling fluid 29 in external thin channel 17 will all be liquid. Cooling fluid 24 will be primarily stationary, not a lot of circulation at that low power in primary fluid loop 21. In this case low power is about 0-3.5 W input power into the device. The temperature for primary fluid loop 21 will be from about ambient temperature 15° C. to the boiling point, which typically is about 65° C. However, the boiling point can change depending on the fluid, altitude, and other factors 65° C. is the boiling point if methanol is used as cooling fluid 24.

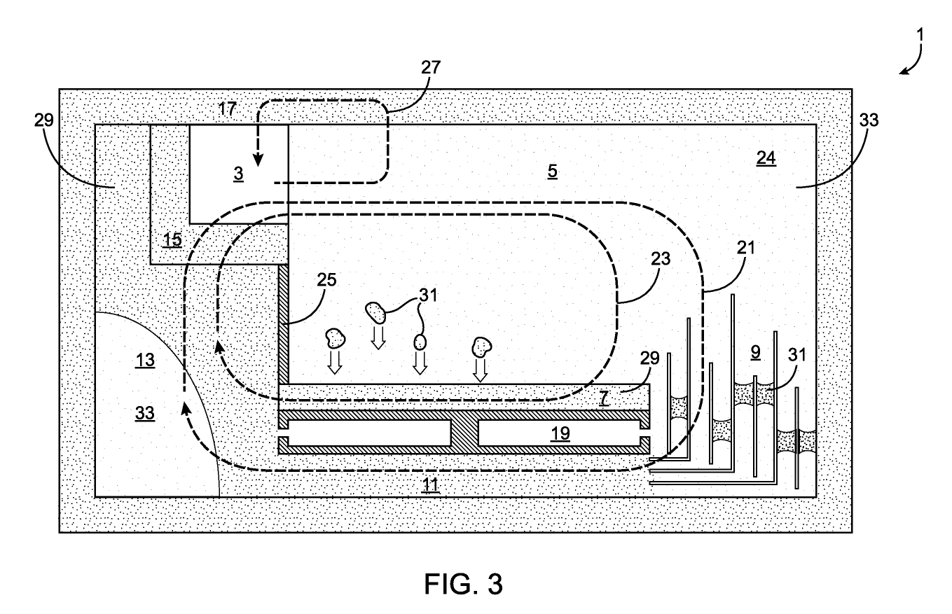

FIG. 3 illustrates an embodiment of the ChillFlex system where second fluid loop 23 dominates. Second fluid loop 23 becomes dominant at from about 3.5-5 W, specifically at about 3.5-4.5 W. In this state of second fluid loop 23, cooling fluid 24 is both in the form of liquid and includes some vapor 33 in compensation chamber 13. Cooling fluid 24 includes some droplet 31 formation in condenser region 9.

Cooling fluid 24 will be in the state of some quantity of liquid 29 in secondary wick 7, in this case more in the form of droplets 31, but differing in shape. The droplets that form in vapor region 5 form near secondary wick 7. Cooling fluid 24 droplets that form in vapor region 5 have a downward movement towards secondary wick 7. These are the same cooling fluid 24 droplets, but forming in vapor region 5.

Further downstream in the fluid dynamic flow, droplets 31 in cooling fluid 24 travel into condenser region 9. However, in this case, rather than being viscously attached to features, droplets 31 are free floating. In condenser region 9, these droplets are forming as a result of fin features in condenser region 9, as shown.

The cooling fluid 24 change in state in this mode is distinguished from when second fluid loop 23 is the primary loop. In this case, the droplets 31 are forming because the liquid is moving so quickly that vapor 33 cannot travel all the way to condenser region 9. Thus, vapor 33 has to condense in an earlier stage. In vapor region 5, cooling fluid 24 is primarily in vapor form with some drops forming.

The ChillFlex functionality between that shown in FIG. 2 and FIG. 3, is that in FIG. 2 primary fluid loop 21 dominates over the other fluid loops in its relative movement. Fluid loop 21 is essentially the largest loop, and theoretically has the most resistance in the loop. Fluid loop 21 is generally a stable, continuous loop. Fluid loop 21 has a lot of resistance, but because the power and velocity is low, the physical resistance is also low. As velocity cooling fluid 24 increases, resistance increases. This resistance is the friction of the cooling fluid 24 against the internal surfaces of the ChillFlex device.

In FIG. 3, some portion of cooling fluid 24 still flows through primary fluid loop 21. However, due to the increased velocity of cooling fluid 24, there is more resistance occurring in primary fluid loop 21. As a result, some cooling fluid 24 will travel through primary fluid loop 21. However, an easier to traverse, less resistive loop is formed, second fluid loop 23.

Thus, at higher cooling fluid 24 velocities, second fluid loop 23 will dominate. The ChillFlex system design specifically includes secondary wick 7. This secondary wick 7 ChillFlex system design feature causes second fluid loop 23 to form as a less resistive circulation. Because of the faster velocity which occurs, second fluid loop 23 becomes the dominant circulation pattern. Primary fluid loop 21 in FIG. 2 naturally develops all the way from room temperature to the boiling temperature. Third fluid loop 27 develops once the boiling temperature is reached. This temperature generally stays constant even as power is increased, although it might rise a little bit, as has been shown in experimental data.

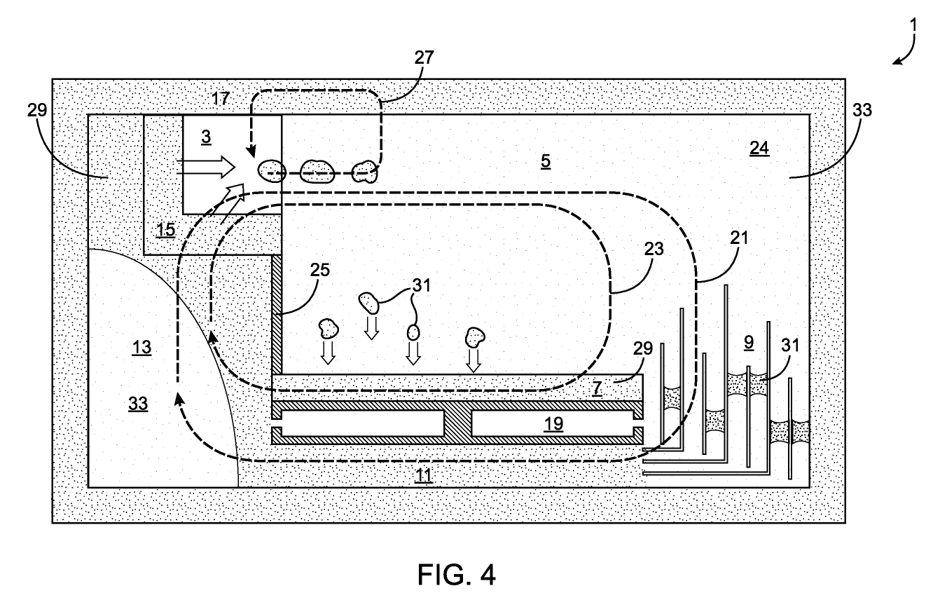

FIG. 4. Illustrates the Chillflex system flow dynamics when cooling fluid 24 flows through third fluid loop 27. Third fluid loop 27 typically dominates at about 5 W watts and above, depending on the particular device design. The highest some of the present inventors typically operate prototype ChillFlex devices is 6 W. However, some have been operated to 8 W, and could be operated at about 10 W.

In these higher energy ChillFlex system operations, third fluid loop 27 is the primary loop. Compensation chamber 13 will contain more vapor 33, although some fluid 29 will remain in return flow area 11. There is still the potential to have droplets 31 forming. As shown in FIG. 4, some cooling fluid 24 is still circulating in primary fluid loop 21. Droplets 31 are forming in condenser region 9. Cooling fluid 24 is in liquid form in return flow area 11, and is circulating up through compensation chamber 13 into primary wick 15. Primary fluid loop 21 is still moving. There are still droplets 31 moving down, that are forming in the bottom of vapor region 5 and traveling down into secondary wick 7

Additionally to the above fluid movement is a force called entrainment. As one theory of the present inventors, entrainment creates third fluid loop 27. Entrainment occurs when vapor is travelling so fast that when there is a phase change from liquid to vapor, additional liquid is pulled from the wick into the evaporator in droplet form. This effect creates droplets 31 which form as cooling fluid 24 exits evaporator structure 3. Because droplets 31 are larger, have more mass, and are being pulled by the vapor, they will then prefer to travel short distance, so they travel up and connect with external thin channel 17. Cooling fluid 24 then circulates back through external thin channel 17, back into the evaporator structure 3. This loop sequence allows for heat to be moved very quickly, so this dynamic shift happens very rapidly.

As cooling fluid 24 flows from primary wick 15 into evaporator structure 3, the liquid is pulled to form drop 31 that will start in evaporator structure 33. Drop 31 is pulled along third fluid loop 27. It is key that the other two loops, primary fluid loop 21 and second fluid loop 23, are still happening. Third fluid loop 27 is just an additional loop that occurs to move even more heat faster.

As a result, third fluid loop 27 is highly responsive to the environmental challenges. If the power dropped below about 5 W, third fluid loop 27 would stop, and not continue. This dynamic happens very specifically, and the ChillFlex system would return to the state of FIG. 3. Third fluid loop 27 is dynamic and responsive. The term in fluid mechanics for this quality is that this is a reversible loop. There is a response time, but the effect will cycle through. The dynamic response of the ChillFlex system to heat removal demands shown in FIGS. 2, 3 and 4 for the purposes of illustration have been shown in three separate states. However, in actually practice, these states flow from one to another as a building continuum.

Primary fluid loop 21, second fluid loop 23, and third fluid loop 27, shift together synergistically in response to heat removal needs as a continuum. As heat removal demands rise, once cooling fluid 24 starts to flow through the second fluid loop 23, the cooling fluid 24 in primary fluid loop 21 is nonetheless still in motion. Once the cooling fluid 24 starts to flow in third fluid loop 27 starts, second fluid loop 23 and primary fluid loop 21 are still happening. There is no full break of the loop. The amount of cooling fluid 24 that flows in the other fluid loops is smaller when you add another fluid loop. In part this is because there is always balancing of the resistance.

Referring to FIG. 4, once third fluid 27 is established, primary fluid loop 21 has higher resistance. Thus, while less cooling fluid 24 will be travelling through primary fluid loop 21, there is still flowing, so the loop is still occurring. Thus, as heat removal demand rises, the ChillFlex system response as primary fluid loop 21 is augmented by second fluid loop 23.

As heat removal demand raises even more, the ChillFlex system responds further as the primary fluid loop 21 and second fluid loop 23 combination is further augmented by the flow of third fluid loop 27. This response provides full dynamic range of heat removal depending on need.

As a result, the ChillFlex device can respond effectively from very low power input to very high power input. Instead of having the entire loop circulate faster, which is what would be necessary in a traditional device, ChillFlex device design allows the loop to travel shorter distances at higher powers so that it can still function in that range. Thus, the ChillFlex device design is responsive rather than determinative.

The breakthrough ChillFlex device design is analogous to meteorological system in the sense that it is like a water balance or water cycle. In these natural heat regulating systems, water flows down to a lake, evaporation occurs, rain falls, and the cycle continues.

Each component in itself balances out the different resistances in the overall system. Considering the loops that are occurring in a meteorological system, ChillFlex device design is very similar, in the sense that each fluid loop in a physically open system is defined by boundaries, based on what is occurring within each of those boundary systems, and each system takes a different power. There a naturally responsive modulation of temperature.

### Fabrication

FIGS. 1-4 illustrate the design of the ChillFlex device. The various components can be realized through various means of fabrication. The main fabrication methods described, as follows, can be employed to produce the larger areas of the ChillFlex device. These include such features as external thin channel 17, compensation chamber 13, return flow area 11, vapor region 5, barrier region 25, and 19. These regions can be fabricated by stamping, casting, or chemical etching methods. These techniques and others like them provide a mass rapid scale process.

Once the basic foundational structure of the ChillFlex device is in place, laser micromachining process can be used for more detailed structural features. By example, condenser region 9, secondary wick 7, primary wick 15, and evaporator structure 3 are made by a laser etched process to provide the small feature size that is required.

Vapor region 5, return flow area 11, compensation chamber 13, and external thin channel 17 are relatively very large areas in the ChillFlex device lacking anything small in their features. These large features can be made with a coarse, low resolution method. By contrast, it is useful to fine tune condenser region 9, secondary wick 7, primary wick 15 and evaporator structure 3 in order to make them small. There is a large general structure that is produced by a sort of a stamping process, and the fine features are produced by laser or other methods, as is understood by one of ordinary skill in the art. The Manufacturing Considerations section, above, provide guidance in this regard.

### Design Parameters & Limitations

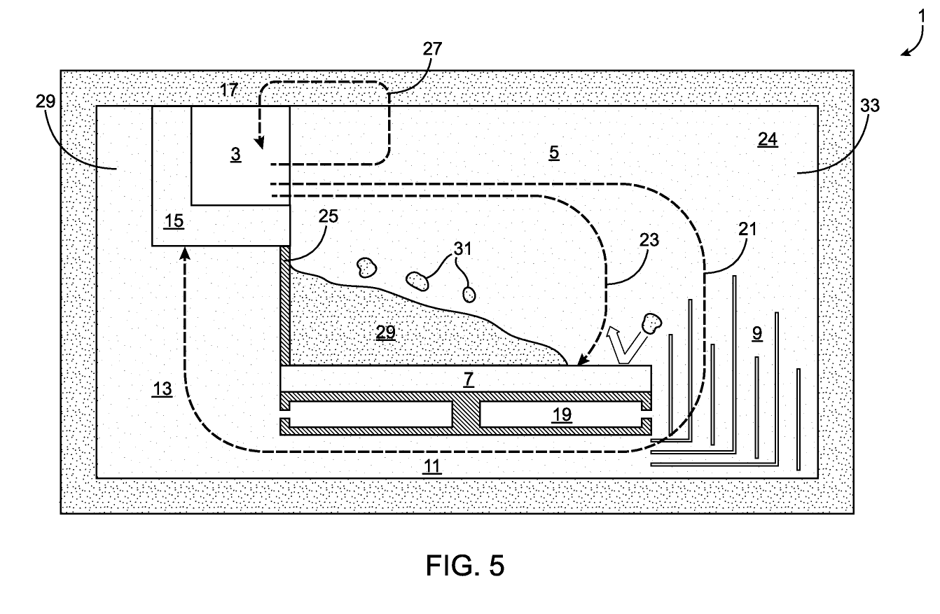

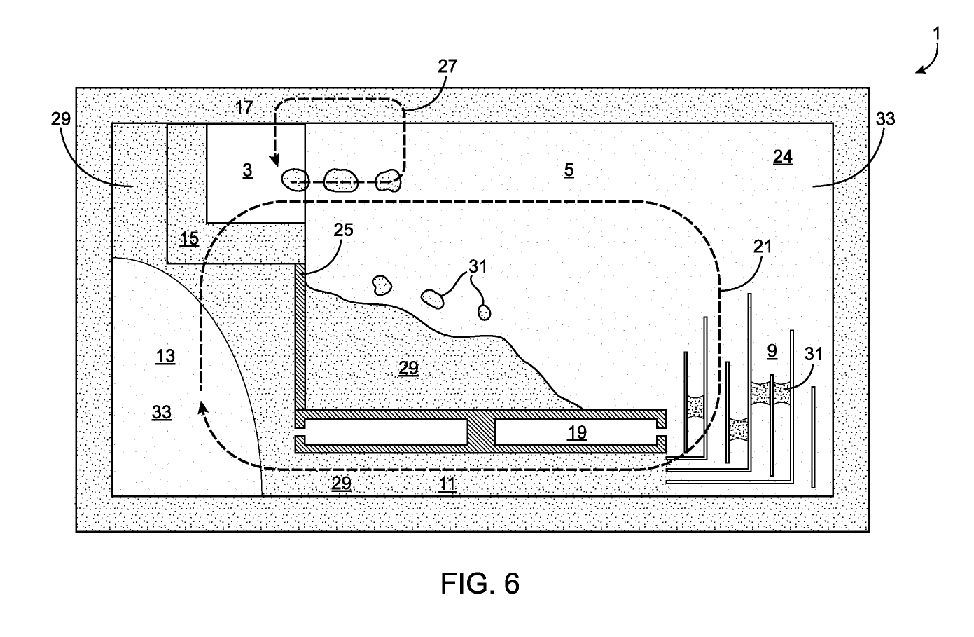

FIG. 5 & FIG. 6 provide illustrations of parameters and boundaries of ChillFlex design functionality. By example, miss-selected design choices for secondary wick 7 and primary wick 15 could so change the fluid dynamics of the ChillFlex system that the device would perform sub-optimally, or fail to function outright.

As shown in FIG. 5, secondary wick 7 and primary wick 15 are wick structures with low complexity. The complexity of the ChillFlex system lies in its multiple loops, rather that difficult to fabricate physical features. Secondary wick 7 and primary wick 15 could be altered in a variety of ways, and can be produced by a myriad of fabrication methods.

What is key is that if secondary wick 7 and primary wick 15 are designed in a manner that limit or stop the function of second fluid loop 23 or third fluid loop 27, the system will be nonfunctional or have its function degraded. The way in which wicks are designed and fabricated must support second fluid loop 23 and third fluid loop 27.

The engineering options for fabricating secondary wick 7 and primary wick 15 given their functional requirements can be understood as seen in FIG. 3. Droplets 31 form in region vapor region 5. Now if these droplets come into contact with a feature, and get stuck, or are rejected or moved away from secondary wick 7, or if for some reason when they touch secondary wick 7, these two things are incompatible, then the loops would stop working. A large mass of fluid would build into vapor region 5, and circulation would not occur.

To provided more details of key ChillFlex design considerations, following are modifications to secondary wick 7 and primary wick 15 that would cause the ChillFlex system to function poorly or result in lack of function. Droplets 31 are forming in vapor region 5. If the design of secondary wick 7 was such that the droplets coming into contact with it were unable to enter that region, that is they were rejected, cooling fluid 24 in the form of liquid 29 would build up in the evaporator region, making this region smaller and smaller. This dynamic will increase the pressure in this region, and at some point stop primary fluid loop 21. Fluid loop 21 is the base loop required for circulation. In summary, if vapor region 5 is full of fluid and there is no fluid in return flow area 11 and compensation chamber 13, then the essential loop will not develop, and the system will function minimally if at all.

In a similar scenario, if primary wick 15 cannot move cooling fluid 24 liquid through it, as in second fluid loop 23 and primary fluid loop 21, if cooling fluid 24 cannot get through primary wick 15, then there is no liquid getting to droplets 31. As a result, it is not possible to have a phase change, and there can be no vapor in vapor region 5. So vapor 33 in vapor region 5, will no longer be there, and a loop cannot form.

One of the prototype devices fabricated by some of the present inventors did not have the secondary wick 7 feature, and second fluid loop 23 did not exist. FIG. 5 shows the region of fluid 29 in vapor region 5 that would form there and eventually stop primary fluid loop 21 from happening. This prototype device worked in a smaller range, but it didn't have the range functionality that is needed. Second fluid loop 23 is required to achieve these key benefits. There was degraded functionality because of this dynamic, which is why this teaching is important.

FIG. 6 provides another example of limitations to avoid in designing various ChillFlex device embodiments, in this case regarding secondary wick 7. Barrier region 25, shade in this illustration, which becomes larger. There is no secondary wick 7. As a result, second fluid loop 23 does not develop.

As higher power demands develop droplets 31 are still forming. However, instead of going to secondary wick 7, droplets 31 creating fluid 29 in vapor region 5. Circulation of third fluid loop 27 would still occur, but the range is different. Third fluid loop 27, this smaller loop, will still occur, but no second fluid loop 23 would form. There would be a point where primary fluid loop 21 was not functioning very well, and then third fluid loop 27 would start working. This would result in a temperature rise rather than a temperature constant when second fluid loop 23 would normally stop working.

If the wick of secondary wick 7 or primary wick 15 has not been engineered appropriately for the ChillFlex system, droplets 31 will not get into them. As a result, second fluid loop 23 would still occur but poorly. There would be a sort of a rejection of the loop because of fluid buildup.

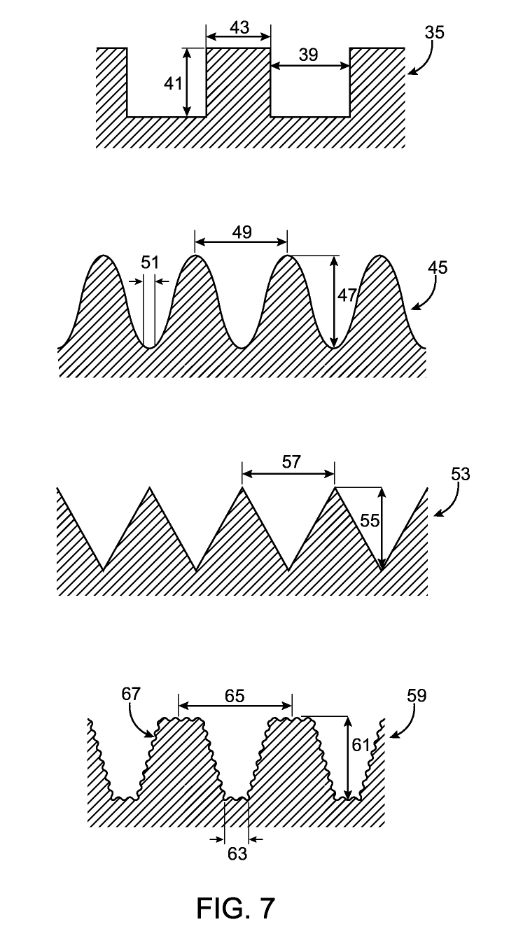

FIG. 7 provides several possible variations of wick structures that could be used for ChillFlex secondary wick 7 and primary wick 15. However, the ChillFlex system in agnostic as to the specific design of the wicks, so these examples are for illustration only.

The proportions of these wick features are generally that they are as wide as they are tall or twice as wide as they are tall, avoiding a middle ground number. This optimization of proportions is due to the effects of capillary forces. If wick features are very deep but not very wide, there will not be increased capillary pressure, but there will be increased resistance.

The ratio of these dimensions is to maximizing capillary forces while minimizing resistance, providing a ratio of those two factors. If different dimensions are required for a specific application, it would be possible to somewhat offset these disadvantages by coating the inside of the interior to minimize resistance.

Typically, as friction or resistance is minimized capillary pressure is minimized. While it is a goal to minimize resistance and maximize capillary pressure, the design effort is normally to push towards optimized pressure. While this could be enhanced by a coating, it is primarily accomplished by optimizing geometric ratios.

Rectangular wick 35 is an example of a basic rectangular wick type structure, a somewhat ideal structure. Some aspects of physical features of rectangular wick 35 are rectangular wick channel width 39, rectangular wick height 41, and rectangular wick solid structure width 43. Included in the structure of rectangular wick 35 are a series of rectangular channels, which result in have rectangular wick channel width 39. The space between the channels is rectangular wick solid structure width 43.

Rectangular wick 35 structures dimension ranges are given as general examples here of a typical ChillFlex embodiment. Rectangular wick channel width 39 ranges from about 25-50 μm. Rectangular wick height 41 ranges from about 25-50 μm. Rectangular wick solid structure width 43 ranges from about 25-50 μm. These ranges are similar for rectangular wick 35, but differ from the wick structures described below.

Wave wick 45 is in the range of available wick designs with more of a rounded structure, with wave wick height 47, wave wick width 49, and wick bottom of the trough size 51. The differentiation of wave wick 45 structural features is they are generally rounded, resulting in a generally more horizontal bottom to the trough. Wave wick height 47 is typically between about 25 μ-50 μm, wave wick width 49 is typically between about 50 μm-100 μm, and trough size 51 is typically about 3 μm-15 μm in this embodiment.

Triangular wick 53 has triangular wick height 55 and triangular wick peak to peak distance 57. Triangular wick 53 and its features have similar ranges to the wick examples above, but does not have a bottom of the trough size due to its angular. The triangular wick height is about 25-50 μm.

While smooth side walls are illustrated for wave wick 45, rectangular wick 35 and triangular wick 53, a useful design feature for each of these wicks is sidewall roughness. Sidewall roughness can maximizes capillary pressure due to the fluid flowing on rough surfaces. Thus, wave wick 45, rectangular wick 35 and triangular wick 53 can have the same basic physical structure, with optimization of function simply by altering the wall surfaces

For illustration as a general example, in this embodiment roughened wick 59 illustrates essentially a similar structure to wave wick 45, but with a roughness to the sidewalls. The roughness can be provided in a variety of different ways. The surface roughness has a natural range. Roughened wick height 61, roughened wick trough base width 63 and roughened wick trough width 65 with sidewall roughness 67.

The walls can be roughened primarily by laser technique or by an etching. By example, a chemical etching can be provided where the surface is eaten away similar to the MEMS concept of DRIE or some kind of chemical etching. This would be analogues to an aluminum based method. Laser processing can also render a rough surface. Traditionally, to get a smooth sidewall, it is first roughened with a laser, and then smoothed by making sort of a molten flow over the surface which smoothes it. In this case, the smoothing step is eliminated. Sandblasting can also be employed to render a rough surface.

Roughened wick height 61 would typically be about 25-50 μm, roughened wick trough base width 63 is typically about 3-15 μm, roughened wick trough width 65 is typically about 50-100 μm, and sidewall roughness 67 RMS roughness in the 10 μm range, with further ranges provided in the examples.

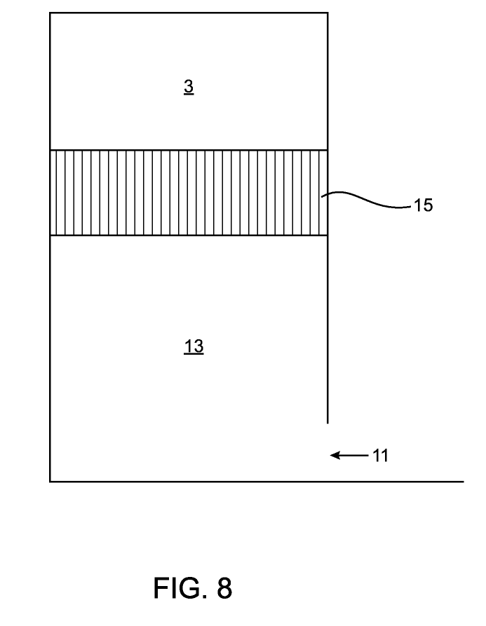

FIG. 8 illustrates alternate evaporator 80. Alternate evaporator 80 is a minimalist structure suitable for certain applications needing optimally large evaporator surface. This large surface can be used to attach multiple heat sources. Alternate evaporator 80 is a different structure which would be substituted for evaporator structure 3. Primary wick 15 and compensation chamber 13 are shown in FIG. 1. However, in the presently describe alternative in FIG. 8, primary wick 15 would be elongated to take over the entire area that compensation chamber 13 occupies in FIG. 1. Instead of having a rectangle with a small rectangle the way that compensation chamber 13 is configures in FIG. 1, compensation chamber 13 would just be as single rectangle. Fluid flow return channel 11 would remain, coming in to the side as in FIG. 1. This would be an alternate approach from the previous wicks that have been discussed. Some of the present inventors constructed and did testing of the structure, which had limited functionality.

The third fluid loop 27 does not occur fully in this alternative structure. In cases where the functionality of third fluid loop 27 is preferably diminished, this could be an appropriate design. The primarily design difference is that the ratio of evaporator structure 3 to primary wick 15 in FIG. 8 is much smaller. There is a lot of evaporator structure 3 and very little primary wick 15. This makes less capillary pressure for a larger evaporator, which diminishes functionality. This is one reason this evaporator structure is not the one for the most efficient device. This is an example of the many different iterations that are available beyond the current embodiment, many more that will be understandable to one of ordinary skill in the art when selecting their design.

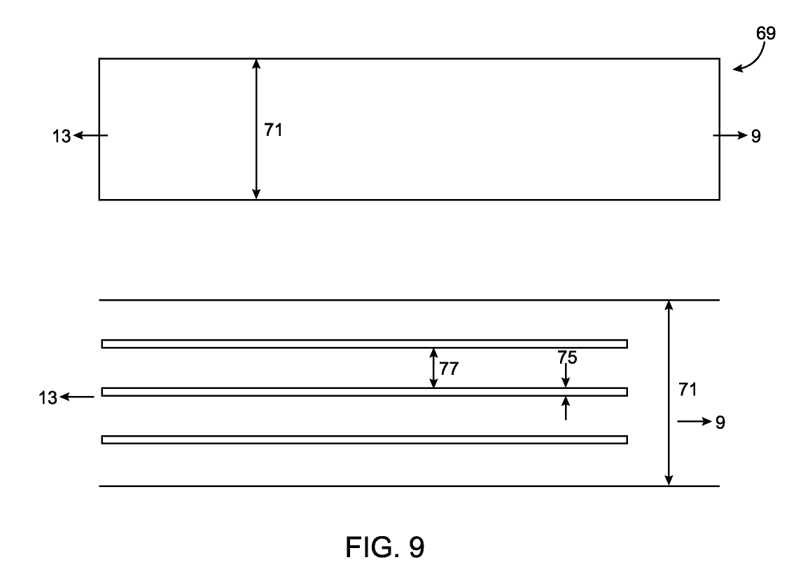

FIG. 9 is an alternate embodiment of the basic device shown in FIG. 1. This provides a basic overview for fluid design channel 69, which consists of one large fluid return channel 71.

Alternate fluid return channel structure 73 has a series of dividing channels to provide more capillary pressure when both fluid and vapor are present in fluid flow return channel 11. There are two ways in which the structure is fabricated. There is one structure which is the base FIG. 11, which is just a large channel. These are both variations on fluid flow return channel 11. Essentially, there is a large channel where one region goes to condenser region 9 and another to compensation chamber 13 and fluid return channel 71. The dimensions range for from about 5-1.25 mm for the one large channel. The channel width 77 and dividing structure width 75 have their own ratios. Dividing structure width 75 is between about 50-200 μm. Channel width 77 is between about 200-500 μm. The overall channel size would be the same as 71, with two channels in it.

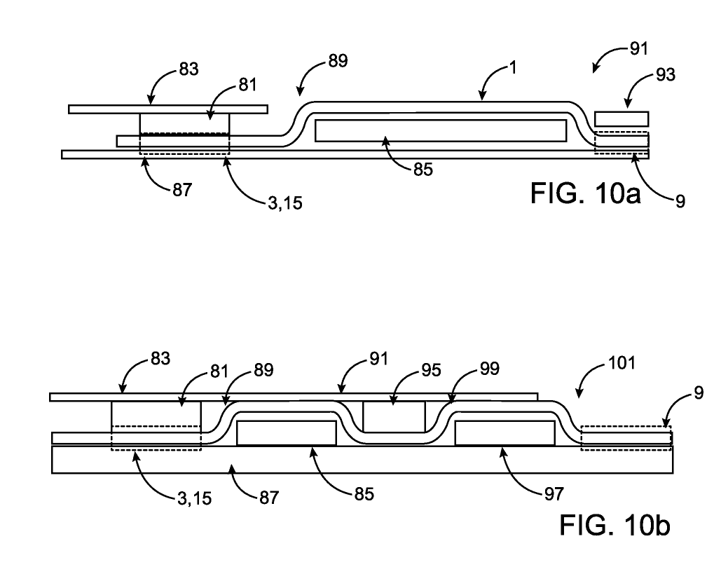

FIG. 10a demonstrates the integration of ChillFlex device 1 with a typical cell phone geometry. Heat source 81 is attached to motherboard 83. In an effort to keep the structure thin, battery 85 is oriented against screen 87. In order to move the heat from heat source 81, ChillFlex device 1 is in contact with heat source 81 and provided with first bend 89, allowing the ChillFlex device 1 to insinuate itself around battery 85. Note that evaporator structure 3 and primary wick 15 are preferably located in unbent regions of ChillFlex device 1. Similarly, note that condenser 9 is also in an unbent region of ChillFlex device 1.

FIG. 10b illustrates a more challenging cooling situation to accommodate a more complex phone component integration. In this situation, ChillFlex device 1 has first bend 89 to allow it to wrap around heat source 81, while still maintaining contact, and over battery 85 that is in contact with the screen 87. In this case, the ChillFlex device 1 second bend 91 allows it to wrap around battery 85 on the battery's second side and to bend under additional chip 95. To accommodate the second battery 97, ChillFlex device 1 is provided with third bend 99 and fourth bend 101. These additional bends allow ChillFlex device 1 to be flush with the screen 87 and second battery 97. Additional bends can be provided to form the ChillFlex device 1 around a power converter or any other chip 93.

Referring now to FIG. 1, there are design considerations for providing bends in ChillFlex device 1. In choosing optimal bend points, it is desirable to have the evaporator structure 3, primary wick 15, and condenser region 9 in relatively flat areas of ChillFlex device 1. Bends are more optimally positioned in other regions of ChillFlex device 1. In general, ChillFlex device 1 can be bent in its middle areas, as long as the evaporator and condenser areas remain generally unbent.

### Mobile Electronic Devices

ChillFlex devices have special advantages when applied to mobile electronic devices. ChillFlex devices will enable specific performance, provide energy savings, and provide overall longer device life. The mobile electronic device cooling market is large, though it currently does not have a solution with thin form factor capable of dissipating heat.

At peak transistor temperatures of about 125° C., ChillFlex reduces device temperatures by about 40%-180%, specifically by about 60%-125%, and more specifically about 90%. At peak transistor temperatures of about 85° C., ChillFlex reduces device temperatures by about 10%-90%, specifically by about 20%-55%, and more specifically by about 30%.

As recognized by major industry players, mobile devices are growing increasingly powerful with faster processors and more cores installed in smaller and thinner packaging. As a result, effective thermal management solutions are important for mobile devices. ChillFlex's ability to spread heat to an insulative plastic cover while conforming to the constraints of small mobile devices will be key in the next generation of mobile devices.

By example, overheating is clearly a key issue in mobile phone failure. As mobile phone systems advance to 4G and higher, overheating issues will only increase. With mid to lower performance phones, to provide competitive pricing, the quality of components and design are sacrificed. This leads to larger overheating issues.

ChillFlex devices have special applicability to these growing mobile phone heating challenges. A passive system with power at 5W+, a thickness of <650 μm, the modular ChillFlex devices can be integrated into current phone designs.

For consumers, the <45° C. device skin temperature means increased market acceptance. Other uses, such as laptops, can have slightly higher skin temperatures. ChillFlex can reduce the device skin temperature to about 25 C.°-65° C., specifically to about 30° C.-50° C., and more specifically about to about 45° C.

The largest thermal gradients exist closest to the source of the heat - the chips themselves. Over a billion smartphones are being shipped in 2013 alone with 40% growth year over year by IDC. With smartphones becoming an essential computing and gaming platform while also becoming very thin, space is at a premium compounding thermal problems.

Heat pipes down to 0.6 mm thick are now being fabricated. However, their performance is heavily compromised with very limited gains demonstrated due to traditional architectures being utilized. Additionally, with low yields in manufacturing below 30%, major smartphone manufacturers are reluctant to adopting them, even with their growing need. The market is potentially vast even assuming only one thermal device per phone at a low price of $0.50/unit

ChillFlex enjoys a high manufacturing yield which will overcome some of these barriers to market entry. The ChillFlex manufacturing yield is from about 40%-100%, specifically from about 60%-90%, and more specifically about 75%.

Mobile chipsets have many difficulties associated with cooling in cell phones. While current chipsets do not produce excessive amounts of heat (<10 W) they are embedded well within the phone and need to spread heat to plastic components (low thermal conductivity) with small temperature differences. Cooling devices are needed that can be to be modularly integrated with little to no changes in phone topology.

ChillFlex, being ultra-thin and bendable to connect with hard to reach hot chips is ideal for cellphone use. Even better, ChillFlex has the ability to then move the heat longer distances to evenly distribute heat all along the less conductive back plate to dissipate the heat.

To maintain comfort, ChillFlex limits temperatures to below 45° C. at maximum performance, while still being able to spread heat to ambient conditions, that being −30° C. in a consumer's hands or pants pocket. ChillFlex is uniquely configured for such a task.

Some examples of currently available, broadly used smart phones which can incorporate the ChillFlex system in their design, increasing battery life and allowing increased processing power, are BlackBerry 010, BlackBerry Z10Sony Xperia Z, Samsung Galaxy Nexus, Samsung Galaxy S3, Samsung Galaxy Note 2, Samsung Galaxy S4, HTC First, HTC Windows Phone 8X, HTC Evo 4G LTE, HTC One X, HTC One X+, HTC Droid DNA; HTC OneApple iPhone 4S, iPhone 5, LG Optimus G, Nexus 4, Nokia Lumia 920, Motorola Droid Razr Maxx HD, among others.

Other smart phones which can be modified to incorporate the ChillFlex system in their design, increasing battery life and allowing increased processing power, are Acer Allegro, Acer beTouch E110, Acer beTouch E130, Acer beTouch E140, Acer DX900, Acer neoTouch, Acer X960, Adaptxt, Android Dev Phone, Baidu Yi, BenQ P30, BlackBerry Porsche Design P′9981, BlackBerry Torch, BlackBerry Torch 9800, BlackBerry Charm, BlackBerry Electron, BlackBerry OS, BlackBerry Pearl, BlackBerry Q10, BlackBerry Q5, BlackBerry Quark, BlackBerry Storm, BlackBerry Storm 2, BlackBerry Style, BlackBerry Tour, BlackBerry Z10, Carrier IQ, Casio G'zOne Commando, Celio Technology Corporation, Comparison of Android devices, Curzon Memories App, CyanogenMod, Dell Streak, Dell Venue Pro, Digital Ocean, Droid Charge, Droid Incredible, Droid Pro, Droid X, FairPhone, Neo 1973, Neo FreeRunner, Find My Phone, Fujitsu Toshiba IS12T,Galaxy Nexus, Garmin Nüvifone, GeeksPhoneKeon, GeeksPhone One, GeeksPhone Peak, Genwi, Google Experience device, Google Nexus, Greenphone, H1droid, Helio Ocean, Hiptop Included Software, Hookflash, HP Veer, HTC 7 Mozart, HTC 7 Pro, HTC 7 Surround, HTC 7 Trophy, HTC Advantage X7500, HTC Butterfly S, HTC Desire, HTC Desire 600, HTC Desire HD, HTC Desire S, HTC Desire Z, HTC Dream, HTC Explorer, HTC HD7, HTC Hero, HTC Legend, HTC Magic, HTC One, HTC Radar, HTC Raider 4G, HTC Rhyme, HTC Sensation, HTC Sensation XL, HTC Smart, HTC Tattoo, HTC Titan, HTC Titan II, HTC Touch 3G, HTC Touch Viva, HTC Wildfire, HTC Wildfire S, HTC Windows Phone 8S, HTC Windows Phone 8X, Huawei IDEOS U8150, Huawei Sonic, Huawei STREAM X GLO7S, Huawei U8230, Huawei U8800, Huawei u8860, I-mate 810-F, IBM Notes Traveler, IBM Simon, Intel AZ210, IOS, IPhone, Iris 3000 Videophone, JavaFX Mobile, Jolla (mobile phone), Kyocera 6035, Kyocera Echo, Kyocera Zio, LG enV Touch, LG eXpo, LG GT540, LG GW620, LG Intuition, LG LU2300, LG Optimus 7, LG Optimus Chat, LG Optimus Chic, LG Optimus One, LG Optimus Vu, LG Quantum, LG VS740, LiMo Foundation, LiMo Platform, Mobilinux, MeeGo, Meizu M8, Meizu M9, Meizu MX, Micromax Canvas 2 A110, Micromax Canvas 2 Plus A110Q, Micromax Canvas HD A116, Micromax Ninja A89, Momentem, Motodext, Motorola A1000, Motorola A760, Motorola A780, Motorola A910, Motorola A925, Motorola Atrix 2, Motorola Atrix 4G, Motorola Backflip, Motorola Calgary, Motorola Defy, Motorola Devour, Motorola Flipout, Motorola i1, Motorola Milestone XT720, Motorola Ming, Motorola Photon, Motorola Photon Q, N-Gage QD, N100 (mobile phone), Nexus 4, Nexus One, Nexus S, Ninetology Black Pearl II, Ninetology Insight, Ninetology Outlook Pure, Ninetology Pearl

Mini, Ninetology Stealth II, Nirvana Phone, Nokia 3230, Nokia 3250, Nokia 3600/3650, Nokia 500, Nokia 5230, Nokia 5250, Nokia 5500 Sport, Nokia 5530 XpressMusic, Nokia 5800 XpressMusic, Nokia 603, Nokia 6110 Navigator, Nokia 6210 Navigator, Nokia 6290, Nokia 6600, Nokia 6620, Nokia 6630, Nokia 6650 fold, Nokia 6670, Nokia 6680, Nokia 6700 slide, Nokia 6710 Navigator, Nokia 6760 Slide, Nokia 700, Nokia 701, Nokia 7610, Nokia 7650, Nokia 7700, Nokia 7710, Nokia 808 PureView, Nokia 9210 Communicator, Nokia 9300, Nokia 9500 Communicator, Nokia Asha 302, Nokia Asha 303, Nokia Asha 311, Nokia Asha 501, Nokia C5-00, Nokia C5-03, Nokia C6-01, Nokia C7-00, Nokia Communicator, Nokia E5-00, Nokia E50, Nokia E51, Nokia E52, Nokia E6, Nokia E60, Nokia E63, Nokia E65, Nokia E66, Nokia E7-00, Nokia E70, Nokia E72, Nokia E75, Nokia E90 Communicator, Nokia Lumia, Nokia Lumia 620, Nokia Lumia 800, Nokia Lumia 810, Nokia Lumia 820, Nokia Lumia 822, Nokia Lumia 900, Nokia Lumia 920, Nokia Lumia 925, Nokia N70, Nokia N71, Nokia N72, Nokia N73, Nokia N75, Nokia N76, Nokia N78, Nokia N79, Nokia N8, Nokia N80, Nokia N81, Nokia N82, Nokia N85, Nokia N86 8 MP, Nokia N9, Nokia N90, Nokia N900, Nokia N91, Nokia N92, Nokia N93, Nokia N93i, Nokia N95, Nokia N950, Nokia N96, Nokia N97, Nokia X5, Nuvifone A50, 02 Xda, Ogo (handheld device), OpenEZX, Openmoko Linux, OPhone, Palm (PDA), Palm Centro, Palm Pixi, Palm Pre, Pantech Vega Racer, Pogo Mobile and nVoy, Samsung Ativ S, Samsung B7610, Samsung Behold II, Samsung Focus, Samsung Focus 2, Samsung Focus S, Samsung Galaxy, Samsung Galaxy Ace, Samsung Galaxy Ace Plus, Samsung Galaxy Core, Samsung Galaxy Fit, Samsung Galaxy Gio, Samsung Galaxy Mini, Samsung Galaxy Note, Samsung Galaxy Note II, Samsung Galaxy Note III, Samsung Galaxy Pocket, Samsung Galaxy Prevail, Samsung Galaxy S Duos, Samsung Galaxy Y DUOS, Samsung Galaxy Y Pro DUOS, Samsung GT-B7320, Samsung GT-B7330, Samsung i5500, Samsung i5700, Samsung i5800, Samsung i7500, Samsung i8000, Samsung i8910, Samsung Minikit, Samsung Omnia 7, Samsung Omnia W, Samsung Replenish, Samsung SGH-i300,Samsung SGH-i900, Samsung SPH-i300, Samsung SPH-i500, Samsung SPH-M810, Samsung SPH-M900, Samsung Wave 575, Shots On-Line, Siemens SX1, Siemens SX45, Smartphone, Smartphone addiction, Smartphone wars, Soft Input Panel, Sony Ericsson Live with Walkman, Sony Ericsson P1, Sony Ericsson P800, Sony Ericsson P900, Sony Ericsson P910, Sony Ericsson P990, Sony Ericsson Satio, Sony Ericsson Vivaz, Sony Ericsson Xperiaacro, Sony Ericsson Xperia Arc, Sony Ericsson Xperia arc S, Sony Ericsson Xperia mini, Sony Ericsson Xperia Mini Pro, Sony Ericsson Xperia neo, Sony Ericsson Xperia neo V, Sony Ericsson Xperia pro, Sony Xperia, Sony Xperia E, Sony Xperia M, Sony Xperia SP, Sony Xperia Z, Sony Xperia ZL, Spice MI-335 (Stellar Craze), Spice Stellar Nhance Mi-435, Super LCD, Symbian,T-Mobile myTouch 4G, T-Mobile myTouch 4G Slide, T-Mobile myTouch Q by LG and T-Mobile myTouch by LG, T-Mobile Pulse, Tizen, Treo 600, Treo 650, Treo 680, Treo 755p, Trium Mondo, Ubuntu Touch, UIQ, Vibo A688, Videophone, Videotelephony, Windows Mobile Smartphone, Windows Phone, Xiaomi MI-One, Xiaomi Phone 2, Xiaomi Phone 2S, Xplore G18, Xplore M98, and ZTE Tania, among others.

### Electronic Tablets

The ChillFlex system's capacity to increase battery life and allow increased processing power has particular advantages as a new feature for electronic tablets. Examples of electronic tables which can usefully include which can usefully incorporate the ChillFlex system in their design, are: iPad Apple A4, Apple A5, Apple A5X, Apple A6X and mini Apple A5, HP Slate 7 8G Tablet Samsung GALAXY NOTE 8.0, Samsung GALAXY NOTE 10.1 among many others.

### Aerospace Systems

There are other applications for the ChillFlex system, such as in aerospace systems. By example, Boeing Company's Space and Intelligence Systems (S&IS) are deeply interested in ChillFlex technology as there is an eminent need for development of advanced thermal management packages, especially those focused on thermal management of satellite and phased array electronics, a high priority for Boeing S&IS.

Iris Technology recognizes the general idea of the ChillFlex's as a potential game changer for high power density electronics of the type they build for the United State Department of Defense. Merlin™ radio power adapters for the AN/PRC-117G tactical radios and our StarPower™ man-portable solar power controller are the types of products that can immediately and measurably benefit from ChillFlex. These are both being procured in the thousands by DoD, representing a significant commercialization potential for ChillFlex technology.

Northrop Grumman Aerospace Systems (NGAS) has explained that traditional measures for satellite thermal management can no longer support the removal of heat from challenges found in hardware such as solid state power amplifiers and flexible data processors. New reliable technology such as ChillFlex needs to be developed to help facilitate thermal management with the progression of electronic systems on satellites. Notwithstanding the appended claims, the disclosure is also defined by the following clauses:
1. A unitary, thin, passive microcooling system integrated into a microelectronic device comprising: a) one or more evaporators; b) a vapor region; c) an optional secondary wick; d) a condenser; e) a compensation chamber; f) a primary wick; g) an optional external thin channel; and h) a cooling fluid; wherein when the microelectronic device heats, one or more fluid loops form responsively in said cooling fluid.
2. The microcooling system of Clause 1, wherein said cooling fluid circulates in a primary fluid loop from said evaporator structure to said vapor region through said condenser into said compensation chamber through said primary wick, returning to said evaporator structure.
3. The microcooling system of Clause 2, where the system draws about 0.0-3.0 W.
4. The microcooling system of Clause 2, wherein said cooling fluid also circulates in a second fluid loop from said evaporator structure to said vapor region into said secondary wick back into said compensation chamber through said primary wick.
5. The microcooling system of Clause 4, where the system draws about 3.0-3.5 W.
6. The microcooling system of Clause 4, wherein said cooling fluid also circulates in a third fluid loop from said evaporator structure into said vapor region through said external thin channel into said evaporator structure.
7. The microcooling system of Clause 6, where the system draws about 3.5-5 W.
8. The microcooling system of Clause 1, where the microcooling system has from 1-5 evaporators.
9. The microcooling system of Clause 8, where the microcooling system has from 2-4 evaporators.
10. The microcooling system of Clause 9, where the microcooling system has 3 evaporators.
11. The microcooling system of Clause 1, where the input power from the microelectronic device is about 0.5 W-20 W.
12. The microcooling system of Clause 11, where the input power from the microelectronic device is about 4 W-10 W.
13. The microcooling system of Clause 12, where the input power from the microelectronic device is about 6 W.
14. The microcooling system of any of the preceding clauses, fabricated of metal, polymer, or ceramic and combinations thereof.
15. The microcooling system of Clause 14, wherein the metal is selected from the group consisting of aluminum, copper, magnesium, steel, stainless steel, alloy steel, titanium, gold, platinum, silver and their alloys, and combinations thereof.
16. The microcooling system of Clause 14, wherein the polymer is selected from the group consisting of carbon fiber-reinforced polymer, polystyrene, phenol formaldehyde resin, neoprene, nylon, polyvinyl chloride, polystyrene, polyethylene, PEO, PET, polypropylene, polyacrylonitrile, PVB, silicone, polysulfone, polyethersulfone, polyetherimide, Polybutylene terephthalate, PPS Polyphenylene Sulfide, polycarbonate, ABS, polyetheretherketone (PEEK), Liquid-Crystal Polymers (LCP), wax, pitch, resins, and combinations thereof.
17. The microcooling system of Clause 14, wherein the ceramic is selected from the group consisting of silicon, silicon carbide, alumina, tungsten carbide, copper oxide, zinc oxide, magnesium oxide, beryllia, ceria, zirconia, carbide, boride, nitride, silicide, aluminum nitride, boron nitride, titanium nitride, and combinations thereof.
18. The microcooling system of any of the preceding clauses, that is about 50μm-950μm thin.
19. The microcooling system of Clause 18, that is about 100μm-650μm thin.
20. The microcooling system of Clause 19, that is about 200μm-550μm thin.
21. The microcooling system of Clause 20, that is about 300μm thin.
22. The microcooling system of any of the preceding clauses, wherein said system has from 1-20 curves.
23. The microcooling system of Clause 22, wherein said system has from 3-10 curves.
24. The microcooling system of Clause 23, wherein said system has from 5-8 curves.
25. The microcooling system of Clause 22, wherein the radius of curvature of the curves is about 0.5-3.0 mm.
26. The microcooling system of Clause 25, wherein the radius of curvature of is about 1.0-2.0 mm.
27. The microcooling system of Clause 26, wherein the radius of curvature is about 1.5 mm.
28. The microcooling system of any of the preceding clauses, wherein the skin temperature of the microelectronic device is maintained at about 25C°-65° C.
29. The microcooling system of Clause 28, wherein the skin temperature of the microelectronic device is maintained at about 30° C.-50° C.
30. The microcooling system of Clause 29, wherein the skin temperature of the microelectronic device is maintained at about 45° C.
31. The microcooling system of any of the preceding clauses, wherein the long distance heat throw from the microelectronic device is about 2 in-10 in.
32. The microcooling system of Clause 31, wherein the long distance heat throw from the microelectronic device is about 3 in-6 in.
33. The microcooling system of Clause 32, wherein the long distance heat throw from the microelectronic device is about 4 in.
34. The microcooling system of any of the preceding clauses, wherein the temperature of the microelectronic device is reduced by about 10%-100%.
35. The microcooling system of Clause 34, wherein the temperature of the microelectronic device is reduced by about 30%-70%.
36. The microcooling system of Clause 35, wherein the temperature of the microelectronic device is reduced by about 50%.
37. The microcooling system of any of the preceding clauses, wherein the temperature of the microelectronic device is reduced by about 1° C.-30° C.
38. The microcooling system of Clause 37, wherein the temperature of the microelectronic device is reduced by about 3° C.-10° C.
39. The microcooling system of Clause 38, wherein the temperature of the microelectronic device is reduced by about 5° C.
40. The microcooling system of any of the preceding clauses, wherein the functional life of the microelectronic device is extended by about 10%-200%.
41. The microcooling system of Clause 40, wherein the functional life of the microelectronic device is extended by about 50%-100%.
42. The microcooling system of Clause 41, wherein the functional life of the microelectronic device is extended by about 75%.
43. The microcooling system of any of the preceding clauses, wherein the functional life of the microelectronic device battery is extended by about 10%-200%.
44. The microcooling system of Clause 43, wherein the functional life of the microelectronic device battery is extended by about 50%-100%.
45. The microcooling system of Clause 44, wherein the functional life of the microelectronic device battery is extended by about 75%.
46. The microcooling system of any of the preceding clauses, wherein the manufacturing yield is about 30%-100%.
47. The microcooling system of Clause 46, wherein the manufacturing yield is about 40%-70%.
48. The microcooling system of Clause 47, wherein the manufacturing yield is about 50%.

All publications and patents cited in this specification are herein incorporated by reference as if each individual publication or patent were specifically and individually indicated to be incorporated by reference and are incorporated herein by reference to disclose and describe the methods and/or materials in connection with which the publications are cited. The citation of any publication is for its disclosure prior to the filing date and should not be construed as an admission that the present disclosure is not entitled to antedate such publication by virtue of prior disclosure. Further, the dates of publication provided may be different from the actual publication dates which may need to be independently confirmed.

It is noted that, as used herein and in the appended claims, the singular forms “a”, “an”, and “the” include plural referents unless the context clearly dictates otherwise. It is further noted that the claims may be drafted to exclude any optional element. As such, this statement is intended to serve as antecedent basis for use of such exclusive terminology as “solely,” “only” and the like in connection with the recitation of claim elements, or use of a “negative” limitation.

As may be apparent to those of skill in the art upon reading this disclosure, each of the individual aspects described and illustrated herein has discrete components and features which may be readily separated from or combined with the features of any of the other several aspects without departing from the scope or spirit of the present disclosure. Any recited method can be carried out in the order of events recited or in any other order which is logically possible.

Although the foregoing disclosure has been described in some detail by way of illustration and example for purposes of clarity of understanding, it is readily apparent to those of ordinary skill in the art in light of the teachings of this disclosure that certain changes and modifications may be made thereto without departing from the spirit or scope of the appended claims.

Accordingly, the preceding merely illustrates the principles of the disclosure. It may be appreciated that those skilled in the art may be able to devise various arrangements which, although not explicitly described or shown herein, embody the principles of the disclosure and are included within its spirit and scope. Furthermore, all examples and conditional language recited herein are principally intended to aid the reader in understanding the principles of the disclosure and the concepts contributed by the inventors to furthering the art, and are to be construed as being without limitation to such specifically recited examples and conditions. Moreover, all statements herein reciting principles, aspects, and aspects of the disclosure as well as specific examples thereof, are intended to encompass both structural and functional equivalents thereof. Additionally, it is intended that such equivalents include both currently known equivalents and equivalents developed in the future, e.g., any elements developed that perform the same function, regardless of structure. The scope of the present disclosure, therefore, is not intended to be limited to the exemplary aspects shown and described herein. Rather, the scope and spirit of present disclosure is embodied by the appended claims.

1. A unitary, thin, passive microcooling system integrated into a microelectronic device comprising:
a) one or more evaporators;
b) a vapor region;
c) an optional secondary wick;
d) a condenser;
e) a compensation chamber;
f) a primary wick;
g) an optional external thin channel; and
h) a cooling fluid;
wherein when the microelectronic device heats, one or more fluid loops form responsively in said cooling fluid.

2. The microcooling system of claim 1, wherein said cooling fluid circulates in a primary fluid loop from said evaporator structure to said vapor region through said condenser into said compensation chamber through said primary wick, returning to said evaporator structure.

3. The microcooling system of claim 2, wherein said cooling fluid also circulates in a second fluid loop from said evaporator structure to said vapor region into said secondary wick back into said compensation chamber through said primary wick.

4. The microcooling system of claim 3, wherein said cooling fluid also circulates in a third fluid loop from said evaporator structure into said vapor region through said external thin channel into said evaporator structure.

5. The microcooling system of claim 1, where the microcooling system has from 1-5 evaporators.

6. The microcooling system of claim 1, where the input power from the microelectronic device is about 0.5 W-20 W.

7. The microcooling system of claim 1, fabricated of metal, polymer, or ceramic and combinations thereof.

8. The microcooling system of claim 7, wherein the metal is selected from the group consisting of aluminum, copper, magnesium, steel, stainless steel, alloy steel, titanium, gold, platinum, silver and their alloys, and combinations thereof.

9. The microcooling system of claim 7, wherein the polymer is selected from the group consisting of carbon fiber-reinforced polymer, polystyrene, phenol formaldehyde resin, neoprene, nylon, polyvinyl chloride, polystyrene, polyethylene, PEO, PET, polypropylene, polyacrylonitrile, PVB, silicone, polysulfone, polyethersulfone, polyetherimide, Polybutylene terephthalate, PPS Polyphenylene Sulfide, polycarbonate, ABS, polyetheretherketone (PEEK), Liquid-Crystal Polymers (LCP), wax, pitch, resins, and combinations thereof.

10. The microcooling system of claim 7, wherein the ceramic is selected from the group consisting of silicon, silicon carbide, alumina, tungsten carbide, copper oxide, zinc oxide, magnesium oxide, beryllia, ceria, zirconia, carbide, boride, nitride, silicide, aluminum nitride, boron nitride, titanium nitride, and combinations thereof.

11. The microcooling system of claim 1, that is about 50 μm-950 μm thin.

12. The microcooling system of claim 1, wherein said system has from 1-20 curves.

13. The microcooling system of claim 1, wherein the skin temperature of the microelectronic device is maintained at about 25 C.°-65° C.

14. The microcooling system of claim 1, wherein the long distance heat throw from the microelectronic device is about 2 in-10 in.

15. The microcooling system of claim 1, wherein the functional life of the microelectronic device is extended by about 10%-200%.
